(19) United States
(12) Patent Application Publication
(10) Pub. No.: US 2025/0147418 A1
(43) Pub. Date: May 8, 2025

(54) PHOTOSENSITIVE RESIN COMPOSITION, METHOD FOR PRODUCING RESIST PATTERN FILM, AND METHOD FOR PRODUCING PLATED SHAPED ARTICLE

(71) Applicant: JSR CORPORATION, Tokyo (JP)

(72) Inventors: Naoki NISHIGUCHI, Minato-ku, Tokyo (JP); Ayako ENDO, Minato-ku, Tokyo (JP); Tomoyuki MATSUMOTO, Minato-ku, Tokyo (JP)

(73) Assignee: JSR CORPORATION, Tokyo (JP)

(21) Appl. No.: 18/838,028

(22) PCT Filed: Feb. 13, 2023
(86) PCT No.: PCT/JP2023/004775

§ 371 Date: Aug. 13, 2024

(30) Foreign Application Priority Data
Feb. 16, 2022 (JP) 2022-022418

(51) Int. Cl. G03F 7/004; C08K 5/45; C09D 133/06; C09D 161/18; C25D 5/02; G03F 7/038; G03F 7/039; H01L 21/288

(52) U.S. Cl. CPC G03F 7/0045; C08K 5/45; C09D 133/066; C09D 161/18; G03F 7/0046; G03F 7/0048; G03F 7/0382; G03F 7/0388; G03F 7/0397; H01L 21/288; C25D 5/022

(57) ABSTRACT

A photosensitive resin composition includes a polymer (A), a photoacid generator (B), and an organic solvent (C). The polymer (A) includes: a structural unit having a phenolic hydroxy group; and a (meth)acrylate-derived structural unit having an acid-dissociable group. The organic solvent (C) includes 3-ethoxyethyl propionate. A solid content concentration of the photosensitive resin composition is 30 mass % or more.

### TECHNICAL FIELD

The present invention relates to a photosensitive resin composition, a method for producing a resist pattern film, and a method for producing a plated shaped article.

### BACKGROUND ART

Performance enhancement of mobile devices such as smartphones and tablet terminals is performed by packaging semiconductor chips having different functions using a high-density packaging technology such as a fan-out wafer level package (FO-WLP), a fan-out panel level package (FO-PLP), a through silicon via (TSV), or a silicon interposer.

In such a packaging technology, wiring and bumps used for electrical connection between semiconductor chips are also increasing in density. Therefore, a fine and high-density resist pattern film used for forming wiring and bumps is also required.

Usually, wiring and bumps are plated shaped articles, and are produced by applying a photosensitive resin composition onto a metal film such as a copper film of a substrate having the metal film to form a resist coating film, exposing and developing the resist coating film using a mask to form a resist pattern film, and performing a plating treatment on the substrate using the resist pattern film as a mold (see Patent Literatures 1 and 2).

The resist coating film is formed by applying a photosensitive resin composition onto a substrate, followed by heating and drying, but a defect of air bubble inclusion in the resist coating film (application bubbles) may occur. When the resist coating film has many application bubbles, there is a problem that it is difficult to obtain a fine and high-density resist pattern film.

Application bubbles may occur when a component contained in a film becomes a gas during heating and drying after application and remains in the film. In addition, in the formation of a resist coating film having a large film thickness, the photosensitive resin composition to be applied needs to have a relatively high viscosity. Therefore, when the photosensitive resin composition is applied onto a substrate having an underlying step, the photosensitive resin composition is not sufficiently applied to the step portion, “bubble entrainment” in which voids remain as bubbles occurs, and application bubbles caused by this may occur.

It is considered that application bubbles caused by “bubble entrainment” are likely to occur due to an increase in viscosity of the resin composition and a decrease in coating applicability/followability as the solvent gradually evaporates during spin coating application, and in order to prevent this, it is considered to use a high-boiling point solvent as the solvent in the photosensitive resin composition. As an example of using a high-boiling point solvent as the solvent in the photosensitive resin composition, for example, a photosensitive composition containing a solvent mixture of propylene glycol methyl ether acetate (PGMEA) and 3-methoxybutyl acetate (3MBA) has been proposed (see Patent Literature 3). However, according to the findings of the present inventor, even when these solvents are used, there is a problem that bubble entrainment in which voids remain as bubbles described above and application bubbles generated by vaporization of a component in the photosensitive resin composition cannot be prevented.

### CITATION LIST

### Patent Literature

Patent Literature 1: JP 2010-008972 A
Patent Literature 2: JP 2006-330368 A
Patent Literature 3: JP 5778568 B2

### SUMMARY OF INVENTION

### Technical Problem

As described above, there is a problem that application bubbles remaining as bubbles at the time of application or generated by vaporization of a component in the photosensitive resin composition cannot be prevented even when a solvent having a high boiling point is used as a solvent in the resin composition, and this problem is particularly remarkable when a resist pattern film having a large film thickness is produced. According to the study of the present inventor, it has been considered that the application bubbles are generated due to the fact that, in a stage where the photosensitive resin composition is applied onto a substrate and heated and dried, a solvent in the vicinity of the surface of the applied material evaporates to form a dry film on the surface, and bubbles generated inside do not escape and remain as application bubbles.

In order to produce a fine and high-density resist pattern film, the appearance of a photosensitive resin composition capable of further preventing the occurrence of application bubbles is required even in the case of producing a resist coating film having a large film thickness. An object of the present invention is to provide a photosensitive resin composition which has excellent solvent evaporability and is capable of producing a resist coating film in which the generation of application bubbles is sufficiently prevented, and to provide a method for producing a resist pattern film using the photosensitive resin composition, and a method for producing a plated shaped article using the resist pattern film.

### Solution to Problem

The present inventor conducted studies in order to solve the above problems. As a result, the present inventor found that the above problems can be solved by a photosensitive resin composition having the following configuration, and completed the present invention. That is, the present invention relates to, for example, the following [1] to [13].
[1]

A photosensitive resin composition containing
a polymer (A) that has a structural unit having a phenolic hydroxy group and a (meth)acrylate-derived structural unit having an acid-dissociable group, a photoacid generator (B), and
an organic solvent (C) that contains 3-ethoxyethyl propionate,
in which a solid content concentration is 30 mass % or more.
[2]

The photosensitive resin composition according to [1], in which the photoacid generator (B) contains a compound represented by a formula (B1) below.

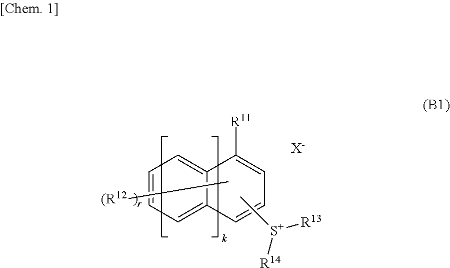

In the formula (B1), R¹¹ is a hydrogen atom, a fluorine atom, a hydroxy group, an alkyl group having 1 to 10 carbon atoms, an alkoxy group having 1 to 10 carbon atoms, or an alkoxycarbonyl group having 2 to 11 carbon atoms, R¹² is an alkyl group having 1 to 10 carbon atoms, an alkoxy group having 1 to 10 carbon atoms, an alkanesulfonyl group or an arylthio group having 1 to 10 carbon atoms, R¹³ and R¹⁴ are each independently an unsubstituted or substituted alkyl group having 1 to 10 carbon atoms, an unsubstituted or substituted phenyl group or naphthyl group, or R¹³ and R¹⁴ may be bonded to each other to form a divalent group having 2 to 10 carbon atoms, k is an integer of 0 to 2, r is an integer of 0 to 10, X⁻ is an anion represented by any of formulae (b-1) to (b-4) below, PF₆⁻, BF4⁻, (CF₃CF₂)₃PF₃⁻, (C₆F₅)₄B⁻, and ((CF₃)₂C₆H₃)₄B⁻.

R¹⁵CₚH_{q}FᵣSO₃⁻: (b-1)

R¹⁵SO₃⁻: (b-2)

In the formulae (b-1) and (b-2), R¹⁵ is a hydrogen atom, a fluorine atom, or a hydrocarbon group having 1 to 12 carbon atoms which may contain a substituent, p is an integer of 1 to 10, q and r are integers satisfying 2p=q+r, and r≠0.

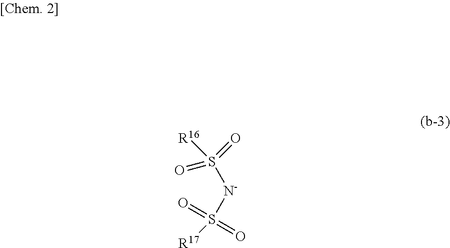

In the formula (b-3), R¹⁶ and R¹⁷ are each independently a fluorine-substituted alkyl group having 1 to 10 carbon atoms, R¹⁶ and R¹⁷ may be bonded to each other to form a divalent fluorine-substituted alkylene group having 2 to 10 carbon atoms.

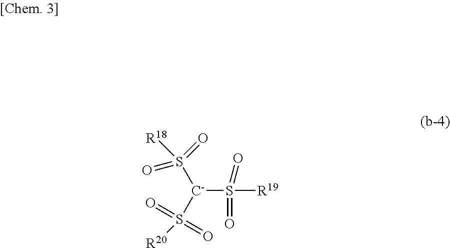

In the formula (b-4), R¹⁸, R¹⁹, and R²⁰ are each independently a fluorine-substituted alkyl group having 1 to 10 carbon atoms, and two of R¹⁸, R¹⁹, and R²⁰ may be bonded to each other to form a divalent fluorine-substituted alkylene group having 2 to 10 carbon atoms.
[3]

The photosensitive resin composition according to [1] or [2], in which the organic solvent (C) further contains an organic solvent which is other than 3-ethoxyethyl propionate and has a boiling point in a range of 120° C. to 180° C.
[4]

The photosensitive resin composition according to any one of [1] to [3], in which the organic solvent (C) contains at least one organic solvent selected from a group consisting of propylene glycol methyl ether acetate (PGMEA), 3-methoxybutyl acetate (3MBA), 3-methoxymethyl propionate, diethylene glycol methyl ethyl ether, 2-heptanone, and ethyl lactate.
[5]

The photosensitive resin composition according to any one of [1] to [4], in which the organic solvent (C) contains at least one organic solvent selected from propylene glycol methyl ether acetate and 3-methoxybutyl acetate.
[6]

The photosensitive resin composition according to any one of [1] to [5], in which the organic solvent (C) contains 20 mass % or more of 3-ethoxyethyl propionate.
[7]

A method for producing a resist pattern film, the method including a step (1) of applying the photosensitive resin composition according to any one of [1] to [6] onto a substrate to form a resin coating film, a step (2) of exposing the resin coating film to light, and a step (3) of developing the resin coating film after exposure.
[8]

The method for producing a resist pattern film according to [7], in which a resulting resist pattern is a line-and-space pattern.
[9]

The method for producing a resist pattern film according to [7], in which a resulting resist pattern is a circular or polygonal columnar pattern.
[10]

The method for producing a resist pattern film according to any one of [7] to [9], in which a film thickness of the resin coating film is 20 μm or more.
[11]

A method for producing a plated shaped article, the method including the method for producing a resist pattern film according to any one of [7] to [10], and further including a step (4) of performing a plating treatment on the substrate using the resist pattern film as a mask. That is, a method for producing a plated shaped article, the method including a step of producing a resist pattern film by the method for producing a resist pattern film according to any one of [7] to [10], and a step (4) of performing a plating treatment on the substrate using the resist pattern film as a mask.
[12]

The method for producing a plated shaped article according to [11], in which a resulting plated shaped article has a line shape.
[13]

The method for producing a plated shaped article according to [11], in which a resulting plated shaped article is a circular or polygonal columnar pattern.

### Advantageous Effects of Invention

According to the present invention, it is possible to provide a photosensitive resin composition which has excellent solvent evaporability and is capable of producing a resist coating film in which the generation of application bubble defects due to, for example, the bubble entrainment is sufficiently prevented, and to provide a method for producing a resist pattern film using the photosensitive resin composition, and a method for producing a plated shaped article using the resist pattern film.

### DESCRIPTION OF EMBODIMENTS

Hereinafter, the present invention will be specifically described.

As each component exemplified in the present description, for example, each component in the photosensitive resin composition and each structural unit in the polymer (A), one type may be contained alone or two or more types may be contained unless otherwise specified.

### <Photosensitive Resin Composition>

The photosensitive resin composition of the present invention contains a specific polymer (A), a photoacid generator (B), and a specific organic solvent (C). The photosensitive resin composition of the present invention may contain other optional components as long as the object of the present invention is not impaired.

### [Polymer (A)]

The polymer (A) contained in the photosensitive resin composition of the present invention is a polymer that has a structural unit having a phenolic hydroxy group and a (meth)acrylate-derived structural unit having an acid-dissociable group. The polymer (A) according to the present invention may have another structural unit other than the structural unit having a phenolic hydroxy group and the (meth)acrylate-derived structural unit having an acid-dissociable group.

### Structural Unit Having Phenolic Hydroxy Group

The polymer (A) has a structural unit having one type or two or more types of phenolic hydroxy groups. When the polymer (A) has a structural unit having a phenolic hydroxy group, the photosensitive resin composition containing the polymer (A) has good alkali solubility, so that the photosensitive resin composition has resolution in a thick film, and a resist pattern film which is resistant to pushing due to plating stress or swelling due to a plating solution at the time of forming a plated shaped article with various plating solutions can be formed.

Examples of the structural unit having a phenolic hydroxy group include a structural unit derived from a monomer having a hydroxyaryl group such as 2-hydroxystyrene, 4-hydroxystyrene, 4-isopropenylphenol, 4-hydroxy-1-vinylnaphthalene, 4-hydroxy-2-vinylnaphthalene, or 4-hydroxyphenyl (meth)acrylate. Examples of the hydroxyaryl group include hydroxyphenyl groups such as a hydroxyphenyl group, a methylhydroxyphenyl group, a dimethylhydroxyphenyl group, a dichlorohydroxyphenyl group, a trihydroxyphenyl group, and a tetrahydroxyphenyl group; and hydroxynaphthyl groups such as a hydroxynaphthyl group and a dihydroxynaphthyl group.

The content ratio of the structural unit having a phenolic hydroxy group in the polymer (A) is preferably 5 to 80 wt %, and more preferably 10 to 70 wt % with respect to all structural units contained in the polymer (A). By setting the content ratio of the structural unit having a phenolic hydroxy group within the above range, optional alkali developability can be imparted, and plating resistance against pushing from plating can be imparted.

### (Meth)acrylate-Derived Structural Unit Having Acid-Dissociable Group

The polymer (A) has one type or two or more types of (meth)acrylate-derived structural units having an acid-dissociable group.

In the present invention, the (meth)acrylate is a generic term for acrylate and methacrylate, and the (meth)acrylate-derived structural unit having an acid-dissociable group contained in the polymer (A) is an acrylate-derived structural unit having an acid-dissociable group or a methacrylate-derived structural unit having an acid-dissociable group. Here, the “acid-dissociable group” is a group that can be dissociated by the action of an acid generated from the photoacid generator (B) described later, and is a group that is substituted for a hydrogen atom of a polar group such as a carboxy group, a hydroxy group, an amino group, or a sulfo group.

The (meth)acrylate-derived structural unit having an acid-dissociable group may be a structural unit derived from an acrylate or a methacrylate and having an acid-dissociable group, and the structure, position, number, for example, of the acid-dissociable group are not particularly limited.

### Acrylate-Derived Structural Unit Having Acid-Dissociable Group

As the acrylate-derived structural unit having an acid-dissociable group, for example, a structural unit (1) represented by a formula (1) below can be used. When the polymer (A) according to the present invention has the structural unit (1), the pattern shape of the resist pattern film formed from the radiation-sensitive resin composition is further improved. The polymer (A) having the structural unit (1) can be relatively easily synthesized.

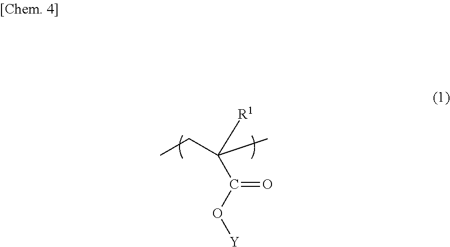

In the formula (1), R¹ is a hydrogen atom, and this hydrogen atom may be substituted with a halogen atom. Examples of the halogen atom that is substituted for a hydrogen atom represented by R¹ include a fluorine atom, a chlorine atom, a bromine atom, and an iodine atom.

Y in the formula (1) is an acid-dissociable group represented by a formula (Y-1) below.

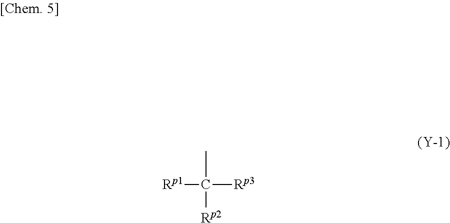

In the formula (Y-1), R^{p1}, R^{p2}, and R^{p3} are each independently a monovalent chain hydrocarbon group having 1 to 5 carbon atoms, a monovalent alicyclic hydrocarbon group having 4 to 20 carbon atoms, or an aromatic hydrocarbon group having 6 to 20 carbon atoms. R^{p2} and R^{p3} are bonded to each other to form a divalent alicyclic hydrocarbon group having 4 to 20 carbon atoms together with the carbon atom to which R^{p2} and R^{p3} are bonded.

Examples of the monovalent chain hydrocarbon group having 1 to 5 carbon atoms represented by R^{p1}, R^{p2}, and R^{P3} in the formula (Y-1) include a monovalent saturated chain hydrocarbon group and an unsaturated chain hydrocarbon group. The monovalent chain hydrocarbon group may be linear or branched.

As R^{p1}, R^{p2}, and R^{P3}, a monovalent saturated chain hydrocarbon group is preferable, and a methyl group, an ethyl group, a n-propyl group, an i-propyl group, a n-butyl group, and a n-pentyl group are preferable, and a methyl group, an ethyl group, an i-propyl group, and a n-pentyl group are more preferable.

Examples of the monovalent alicyclic hydrocarbon group having 4 to 20 carbon atoms represented by R^{p1}, R^{p2}, and R^{P3} in the formula (Y-1) include a monovalent monocyclic saturated cyclic hydrocarbon group, a monocyclic unsaturated cyclic hydrocarbon group, a polycyclic saturated cyclic hydrocarbon group, and a polycyclic unsaturated cyclic hydrocarbon group.

Specific examples of the monovalent monocyclic saturated cyclic hydrocarbon group include a cyclobutyl group, a cyclopentyl group, a cyclohexyl group, a cycloheptyl group, and a cyclooctyl group.

Specific examples of the monovalent monocyclic unsaturated cyclic hydrocarbon group include a cyclobutenyl group, a cyclopentenyl group, and a cyclohexenyl group.

Specific examples of the monovalent polycyclic saturated cyclic hydrocarbon group include a norbornyl group, an adamantyl group, a tricyclodecyl group, and a tetracyclododecyl group.

Specific examples of the monovalent polycyclic unsaturated cyclic hydrocarbon group include a norbornenyl group and a tricyclodecenyl group.

Among them, a monovalent monocyclic saturated cyclic hydrocarbon group and a monovalent polycyclic saturated cyclic hydrocarbon group are preferable, a cyclopentyl group, a cyclohexyl group, a norbornyl group, and an adamantyl group are more preferable, and a cyclohexyl group and an adamantyl group are still more preferable.

Examples of the divalent alicyclic hydrocarbon group formed by bonding R^{p2} and R^{p3} to each other together with the carbon atom to which R^{p2} and R^{p3} are bonded include a divalent monocyclic saturated cyclic hydrocarbon group, a monocyclic unsaturated cyclic hydrocarbon group, a polycyclic saturated cyclic hydrocarbon group, and a polycyclic unsaturated cyclic hydrocarbon group.

Specific examples of the divalent monocyclic saturated cyclic hydrocarbon group include a cyclobutanediyl group, a cyclopentanediyl group, a cyclohexanediyl group, a cyclohexanediyl group, and a cyclooctanediyl group.

Specific examples of the divalent monocyclic unsaturated cyclic hydrocarbon group include a cyclobutenediyl group, a cyclopentenediyl group, and a cyclohexenediyl group.

Specific examples of the divalent polycyclic saturated cyclic hydrocarbon group include a norbornanediyl group, an adamantanediyl group, a tricyclodecanediyl group, and a tetracyclododecanediyl group.

Specific examples of the divalent polycyclic unsaturated cyclic hydrocarbon group include a norbornenediyl group, a tricyclodecenediyl group, and a tetracyclododecenediyl group.

Among them, a divalent monocyclic saturated cyclic hydrocarbon group and a divalent polycyclic saturated cyclic hydrocarbon group are preferable, a cyclopentanediyl group, a cyclohexanediyl group, a cyclooctanediyl group, a norbornanediyl group, and an adamantanediyl group are more preferable, and a cyclopentanediyl group and an adamantanediyl group are still more preferable.

Specific examples of the structural unit (1) described above include structural units represented by formulae (1-1) to (1-4) below.

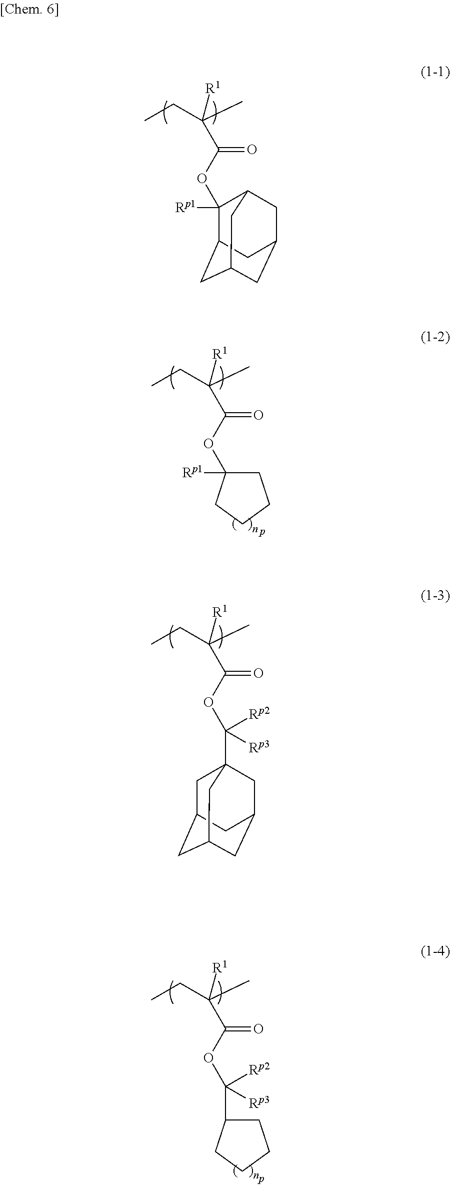

In the formulae (1-1) to (1-4), R¹ has the same meaning as in formula (1), and R^{p1}, R^{p2}, and R^{P3} have the same meanings as in formula (Y-1). nₚ's in the formulae (1-1) to (1-4) are each independently an integer of 1 to 4.

Specific examples of the structural unit represented by the formulae (1-1) to (1-4) include structural units represented by formulae below. In each formula below, R¹ has the same meaning as in the formula (1).

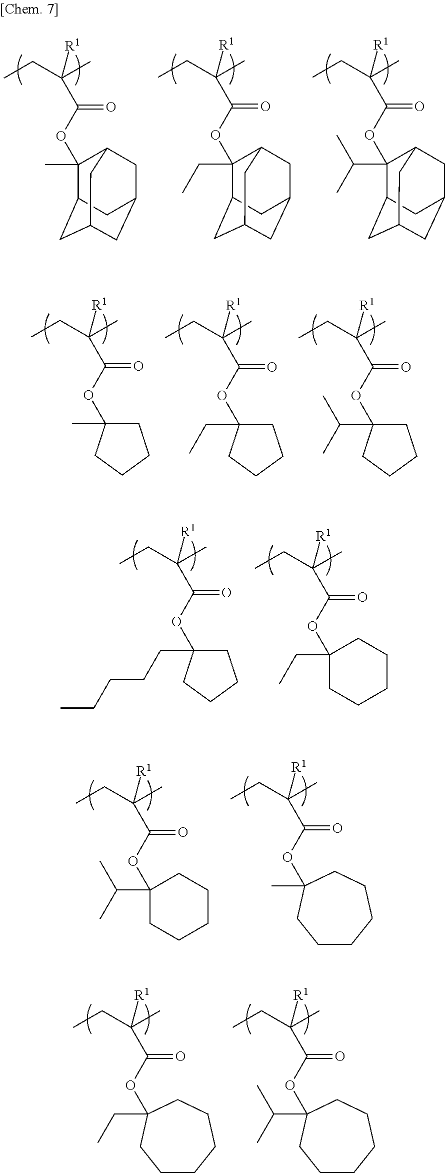

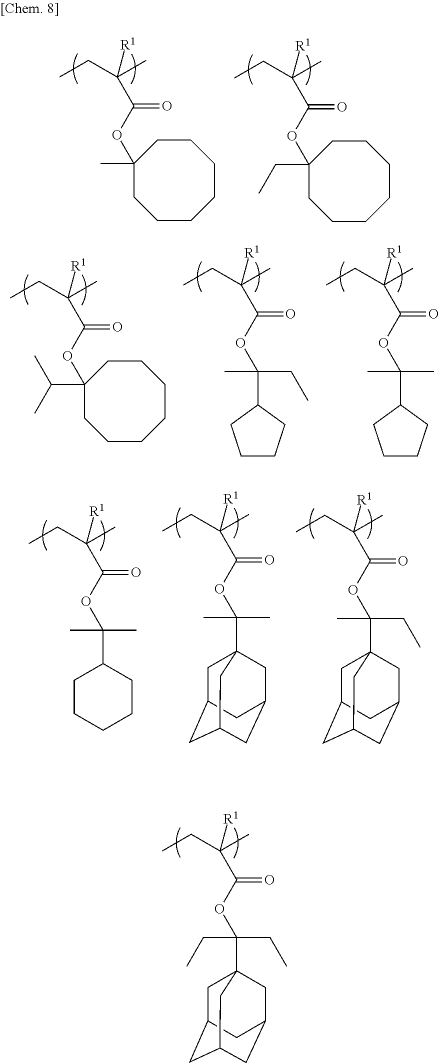

### Methacrylate-Derived Structural Unit Having Acid-Dissociable Group

As the methacrylate-derived structural unit having an acid-dissociable group, for example, a structural unit (2) represented by a formula (2) below can be used. When the polymer (A) according to the present invention has the structural unit (2), the ease of dissociation of the acid-dissociable group is enhanced, and as a result, the pattern shape of the resist pattern film formed from the radiation-sensitive resin composition is further improved. The polymer (A) having the structural unit (2) can be relatively easily synthesized.

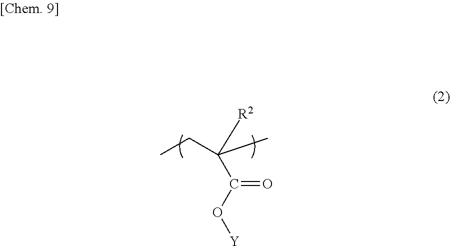

In the formula (2), R² is a methyl group, and some or all hydrogen atoms of the methyl group may be substituted with a halogen atom. Y in the formula (2) is identical to that of the structural unit (1) described above.

Specific examples of the structural unit (2) include structural units represented by formulae (2-1) to (2-4) below.

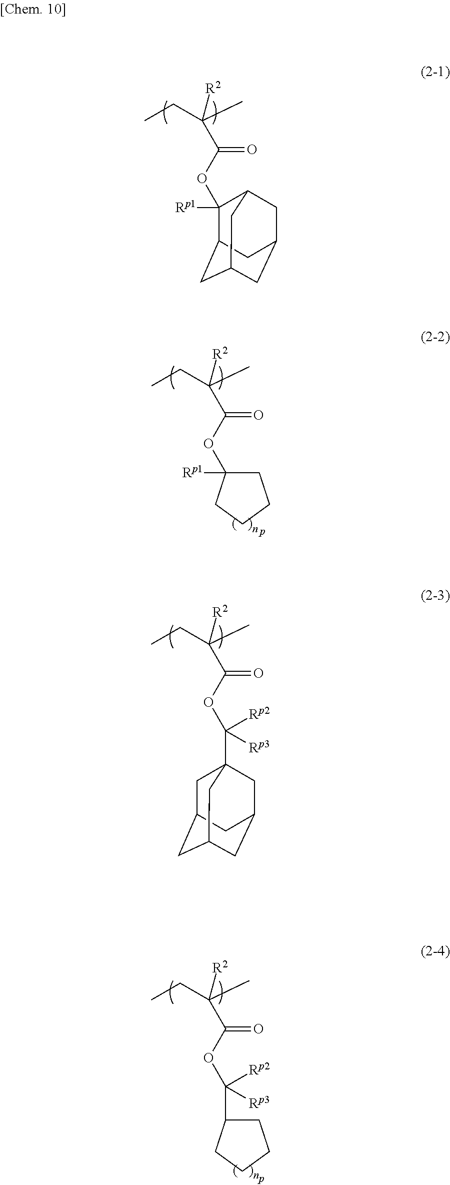

In the formulae (2-1) to (2-4), R² has the same meaning as in the formula (2), and R^{p1}, R^{p2}, and R^{p3} have the same meanings as in the formula (Y-1). nₚ's in the formulae (2-1) to (2-4) are each independently an integer of 1 to 4.

Specific examples of the structural unit represented by the formulae (2-1) to (2-4) include structural units represented by formulae below. In each formula below, R² has the same meaning as in the formula (2).

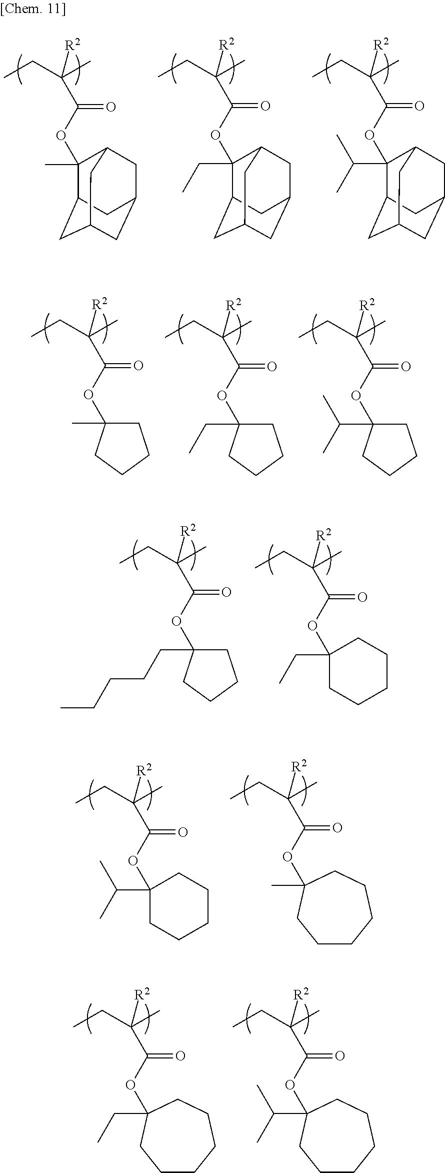

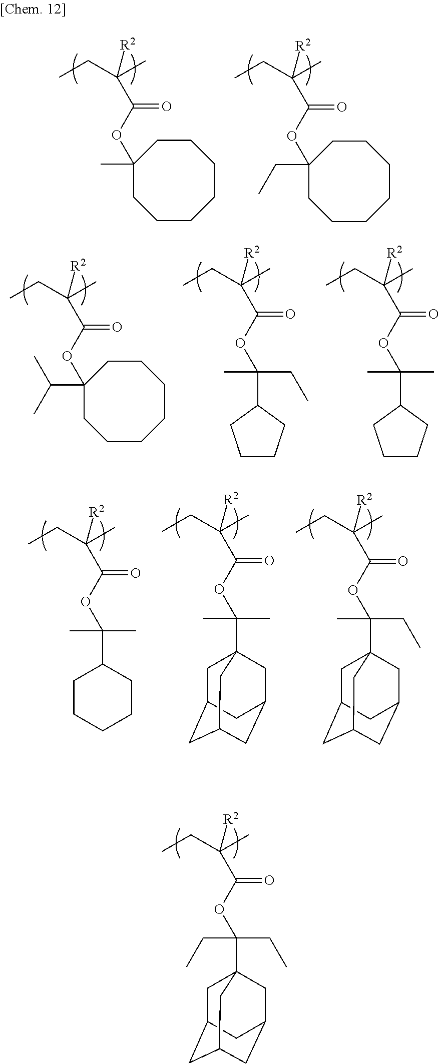

The content ratio of the (meth)acrylate-derived structural unit having an acid-dissociable group in the polymer (A) is preferably 15 to 70 wt % and more preferably 20 to 50 wt % with respect to all structural units contained in the polymer (A). By setting the content ratio of the (meth)acrylate-derived structural unit having an acid-dissociable group within the above range, development defects can be prevented.

### Another Structural Unit

The polymer (A) may further contain another structural unit other than the structural unit having a phenolic hydroxy group and the (meth)acrylate-derived structural unit having an acid-dissociable group as long as the effects of the present invention are not impaired. For example, when the polymer (A) further contains a structural unit containing a hydrophobic group and another structural unit containing a polar group, compatibility between the polymer (A) and other components such as the photoacid generator (B) described later can be regulated, and as a result, development defects can be further prevented.

Examples of the another structural unit containing a hydrophobic group include alkyl (meth)acrylates such as methyl (meth)acrylate, ethyl (meth)acrylate, propyl (meth)acrylate, n-butyl (meth)acrylate, and sec-butyl (meth)acrylate; alkoxyalkyl (meth)acrylates such as methoxyethyl (meth)acrylate and ethoxyethyl (meth)acrylate; and aromatic vinyl monomers such as styrene. Examples of the another structural unit containing a polar group include (meth)acrylic acid.

### Method for Producing Polymer (A)

The polymer (A) can be produced by subjecting a monomer corresponding to each structural unit to a known polymerization method such as an ion polymerization method or a radical polymerization method in an appropriate polymerization solvent. Among them, a radical polymerization method is preferable.

Examples of a radical polymerization initiator used in the radical polymerization method include azo compounds such as 2,2′-azobisisobutyronitrile, 2,2′-azobis(methyl isobutyrate), and 2,2′-azobis-(2,4-dimethylvaleronitrile); and organic peroxides such as benzoyl peroxide, lauryl peroxide, and t-butyl peroxide.

In the polymerization, a molecular weight modifier such as a mercaptan compound or a halogen hydrocarbon can be used as necessary.

Examples of the solvent used for polymerization for the polymer (A) include alkanes, cycloalkanes, aromatic hydrocarbons, halogenated hydrocarbons, saturated carboxylate esters, ketones, ethers, and alcohols.

Specific examples of the alkanes include n-pentane, n-hexane, n-heptane, n-octane, n-nonane, and n-decane.

Specific examples of the cycloalkanes include cyclohexane, cycloheptane, cyclooctane, decalin, and norbornane.

Specific examples of the aromatic hydrocarbons include benzene, toluene, xylene, ethylbenzene, and cumene.

Specific examples of the halogenated hydrocarbons include chlorobutanes, bromohexanes, dichloroethanes, hexamethylene dibromide, and chlorobenzene.

Specific examples of the saturated carboxylate esters include ethyl acetate, n-butyl acetate, i-butyl acetate, and methyl propionate.

Specific examples of the ketones include acetone, 2-butanone, 4-methyl-2-pentanone, and 2-heptanone.

Specific examples of the ethers include tetrahydrofuran, dimethoxyethanes, diethoxyethanes, and diethylene glycol ethyl methyl ether.

Specific examples of the alcohols, for example, include methanol, ethanol, 1-propanol, 2-propanol, and 4-methyl-2 pentanol.

As the solvent, one type can be used alone or two or more types can be used in admixture.

The reaction temperature at the time of polymerization is usually 40° C. to 150° C., and preferably 50° C. to 120° C. The reaction time is usually 1 hour to 48 hours, and preferably 1 hour to 24 hours.

### Polymer (A)

The weight-average molecular weight (Mw) of the polymer (A) measured by gel permeation chromatography (GPC) is preferably 1,000 to 100,000, more preferably 2,000 to 50,000, and still more preferably 3,000 to 30,000. By setting the Mw of the polymer (A) within the above specific range, film loss can be prevented, and development defects can be further prevented.

The ratio (Mw/Mn) of the Mw to the number-average molecular weight (Mn) of the polymer (A) is usually 1 to 5, preferably 1 to 3, and more preferably 1 to 2. By setting Mw/Mn within such a specific range, film loss can be prevented, and development defects can be further prevented.

In the present description, the Mw and Mn of a polymer are values measured by gel permeation chromatography (GPC) under the following conditions.

### (Measurement Conditions by GPC)

GPC column: 2 columns of G2000HXL, 1 column of G3000HXL, and 1 column of G4000HXL, manufactured by Tosoh Corporation
Column temperature: 40° C.
Elution solvent: tetrahydrofuran (manufactured by Wako Pure Chemical Industries, Ltd.)
Flow rate: 1.0 mL/min
Sample concentration: 1.0 mass %
Sample injection amount: 100 μL
Detector: Differential refractometer
Standard substance: Monodisperse polystyrene

In the photosensitive resin composition containing such a polymer (A), the (meth)acrylate-derived structural unit having an acid-dissociable group is dissociated by the photoacid generator (B) described later, and as a result, an acidic functional group such as a carboxy group or a phenolic hydroxy group is generated in the polymer (A). As a result, the solubility of the polymer (A) in an alkaline developer changes, and the photosensitive resin composition according to the present invention enables the formation of a resist pattern film.

### [Photoacid Generator (B)]

The photoacid generator (B) according to the present invention is a compound that generates an acid by the action of light. The photoacid generator in the present invention is a compound that is decomposed by the action of light to produce a compound acting as an acid. That is, a compound that does not produce a compound acting as an acid by being decomposed by the action of light, such as a quinonediazide-based photosensitizer, does not correspond to the photoacid generator (B) according to the present invention. Preferable examples of the photoacid generator (B) according to the present invention include, for example, a compound represented by the formula (B1) below.

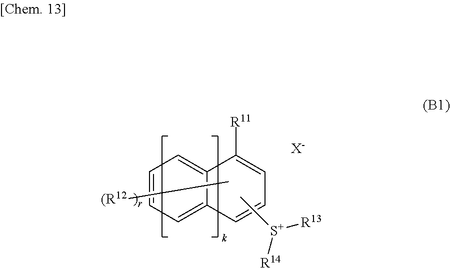

In the formula (B1), R¹¹ is a hydrogen atom, a fluorine atom, a hydroxy group, an alkyl group having 1 to 10 carbon atoms, an alkoxy group having 1 to 10 carbon atoms, or an alkoxycarbonyl group having 2 to 11 carbon atoms, R¹² is an alkyl group having 1 to 10 carbon atoms, an alkoxy group having 1 to 10 carbon atoms, an alkanesulfonyl group or an arylthio group having 1 to 10 carbon atoms, R¹³ and R¹⁴ are each independently an unsubstituted or substituted alkyl group having 1 to 10 carbon atoms, an unsubstituted or substituted phenyl group or naphthyl group, or R¹³ and R¹⁴ may be bonded to each other to form a divalent group having 2 to 10 carbon atoms, k is an integer of 0 to 2, r is an integer of 0 to 10, X⁻ is an anion represented by any of the formulae (b-1) to (b-4) below, PF₆⁻, BF4⁻, (CF₃CF₂)₃PF₃⁻, (C₆F₅)₄B⁻, and ((CF₃)₂C₆H₃)₄B⁻.

R¹⁵CₚH_{q}FᵣSO₃⁻: (b-1)

R¹⁵SO₃⁻: (b-2)

In the formulae (b-1) and (b-2), R¹⁵ is a hydrogen atom, a fluorine atom, or a hydrocarbon group having 1 to 12 carbon atoms which may contain a substituent, p is an integer of 1 to 10, q and r are integers satisfying 2p=q+r, and r≠0.

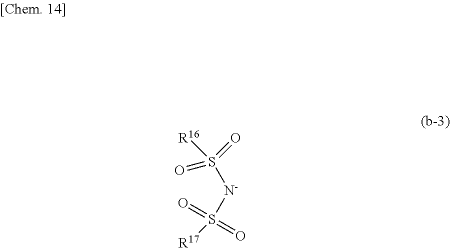

In the formula (b-3), R¹⁶ and R¹⁷ are each independently a fluorine-substituted alkyl group having 1 to 10 carbon atoms, R¹⁶ and R¹⁷ may be bonded to each other to form a divalent fluorine-substituted alkylene group having 2 to 10 carbon atoms.

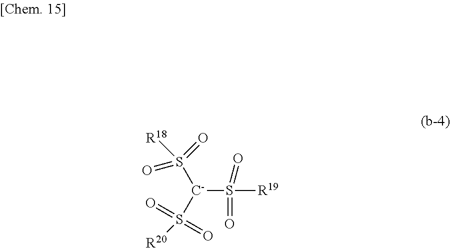

In the formula (b-4), R¹⁸, R¹⁹, and R²⁰ are each independently a fluorine-substituted alkyl group having 1 to 10 carbon atoms, and two of R¹⁸, R¹⁹, and R²⁰ may be bonded to each other to form a divalent fluorine-substituted alkylene group having 2 to 10 carbon atoms.

Examples of the alkyl group having 1 to 10 carbon atoms represented by R¹¹ to R¹⁴ in the formula (B1) include, in addition to the examples of the alkyl group having 1 to 4 carbon atoms, linear alkyl groups such as a n-pentyl group, a n-hexyl group, a n-heptyl group, a n-octyl group, a n-nonyl group, and a n-decyl group; branched alkyl groups such as a neopentyl group and a 2-ethylhexyl group, for example. Among them, a methyl group, an ethyl group, a n-butyl group, and a t-butyl group are preferable.

Examples of the alkoxy group having 1 to 10 carbon atoms represented by R¹¹ and R¹² include linear alkoxy groups such as a methoxy group, an ethoxy group, a n-propoxy group, a n-butoxy group, and a n-hexyloxy group, and branched alkoxy groups such as an i-propoxy group and an i-hexyloxy group. Among them, a methoxy group, an ethoxy group, a n-propoxy group, and a n-butoxy group are preferable.

Examples of the alkoxycarbonyl group having 2 to 11 carbon atoms represented by R¹¹ include linear alkoxycarbonyl groups such as a methoxycarbonyl group, an ethoxycarbonyl group, a n-butoxycarbonyl group and a n-hexyloxycarbonyl group, and branched alkoxycarbonyl groups such as an i-propoxycarbonyl group, and an i-hexyloxycarbonyl group. Among them, a methoxycarbonyl group, an ethoxycarbonyl group, and a n-butoxycarbonyl group are preferable.

Examples of the alkanesulfonyl group having 1 to 10 carbon atoms represented by R¹² include linear alkanesulfonyl groups such as a methanesulfonyl group, an ethanesulfonyl group, a n-propanesulfonyl group, an n-butanesulfonyl group, and a n-hexanesulfonyl group; branched alkanesulfonyl groups such as an i-butanesulfonyl group and an i-hexanesulfonyl group; and cycloalkanesulfonyl groups such as a cyclopentanesulfonyl group, a cyclohexanesulfonyl group, and a cyclooctanesulfonyl group. Among them, a methanesulfonyl group, an ethanesulfonyl group, a n-propanesulfonyl group, a n-butanesulfonyl group, a cyclopentanesulfonyl group, and a cyclohexanesulfonyl group are preferable.

Examples of the aryl group of the arylthio group represented by R¹² include aromatic groups such as a phenyl group and a naphthyl group, and these aromatic groups may have a substituent. Examples of the substituent include halogen, a hydroxy group, an acetyl group, an alkyl group having 1 to 5 carbon atoms, an alkoxy group having 1 to 5 carbon atoms, an alicyclic hydrocarbon group having 5 to 10 carbon atoms, an aromatic hydrocarbon group having 6 to 10 carbon atoms, and a heterocyclic group having 5 to 10 carbon atoms.

In the formula (B1), r is preferably an integer of 0 to 2.

In the formula (B1), k is an integer of 0 to 2. When k is 1 or 2, R¹² may be a substituent of the same aromatic ring as R¹¹ or a substituent of a different ring. k is preferably 0 or 1.

In the formula (B1), examples of the unsubstituted or substituted phenyl group represented by R¹³ and R¹⁴ include substituted phenyl groups such as an o-tolyl group, a m-tolyl group, a p-tolyl group, and a 2,3-dimethylphenyl group in addition to a phenyl group; a group in which some or all hydrogen atoms of these groups are substituted with at least one group selected from the group consisting of a hydroxy group, a carboxy group, a cyano group, a nitro group, an alkoxy group, an alkoxyalkyl group, an alkoxycarbonyl group, and an alkoxycarbonyloxy group, for example.

Among the groups that are substituted for a hydrogen atom of the phenyl group or the substituted phenyl group, examples of the alkoxy group include linear alkoxy groups such as a methoxy group, an ethoxy group, a n-propoxy group, and a n-butoxy group; branched alkoxy groups such as an i-propoxy group, a 2-methylpropoxy group, a 1-methylpropoxy group, and a t-butoxy group; and cycloalkyloxy groups such as a cyclopentyloxy group and a cyclohexyloxy group. The number of carbon atoms in these groups is preferably 1 to 20.

Examples of the alkoxyalkyl group include linear alkoxyalkyl groups such as a methoxymethyl group, an ethoxymethyl group, a 2-methoxyethyl group, and a 2-ethoxyethyl group; branched alkoxyalkyl groups such as 1-methoxyethyl group and 1-ethoxyethyl group; other alkoxyalkyl groups having a cycloalkane structure, for example. The number of carbon atoms in these groups is preferably 1 to 20.

Examples of the alkoxycarbonyl group include linear alkoxycarbonyl groups such as a methoxycarbonyl group, an ethoxycarbonyl group, a n-propoxycarbonyl group, and a n-butoxycarbonyl group; branched alkoxycarbonyl groups such as an i-propoxycarbonyl group, a 2-methylpropoxycarbonyl group, a 1-methylpropoxycarbonyl group, and a t-butoxycarbonyl group; cycloalkyloxycarbonyl groups such as a cyclopentyloxycarbonyl group and a cyclohexyloxycarbonyl group, for example. The number of carbon atoms in these groups is preferably 2 to 21.

Examples of the alkoxycarbonyloxy group include linear alkoxycarbonyloxy groups such as a methoxycarbonyloxy group, an ethoxycarbonyloxy group, a n-propoxycarbonyloxy group, and a n-butoxycarbonyloxy group; branched alkoxycarbonyloxy groups such as i-propoxycarbonyloxy group and t-butoxycarbonyloxy group; cycloalkyloxycarbonyloxy groups such as a cyclopentyloxycarbonyloxy group and a cyclohexyloxycarbonyloxy group, for example. The number of carbon atoms in these groups is preferably 2 to 21.

In the formula (B1), the unsubstituted or substituted phenyl group represented by R¹³ and R¹⁴ is preferably a phenyl group, a 4-cyclohexylphenyl group, a 4-t-butylphenyl group, a 4-methoxyphenyl group, or a 4-t-butoxyphenyl group.

Examples of the unsubstituted or substituted naphthyl group represented by R¹³ and R¹⁴ include substituted naphthyl groups such as a 2-methyl-1-naphthyl group, a 3-methyl-1-naphthyl group, and a 4-methyl-1-naphthyl group in addition to a 1-naphthyl group; a group in which some or all hydrogen atoms of these groups are substituted with at least one group selected from the group consisting of a hydroxy group, a carboxy group, a cyano group, a nitro group, an alkoxy group, an alkoxyalkyl group, an alkoxycarbonyl group, and an alkoxycarbonyloxy group, for example.

Examples of the alkoxy group, the alkoxyalkyl group, the alkoxycarbonyl group, and the alkoxycarbonyloxy group that are substituted for a hydrogen atom of the naphthyl group or the substituted naphthyl group include the groups exemplified in the above section of the phenyl group.

In the formula (B1), the unsubstituted or substituted naphthyl group represented by R¹³ and R¹⁴ is preferably a 1-naphthyl group, a 1-(4-methoxynaphthyl) group, a 1-(4-ethoxynaphthyl) group, a 1-(4-n-propoxynaphthyl) group, a 1-(4-n-butoxynaphthyl) group, a 2-(7-methoxynaphthyl) group, a 2-(7-ethoxynaphthyl) group, a 2-(7-n-propoxynaphthyl) group, or a 2-(7-n-butoxynaphthyl) group.

As the divalent group having 2 to 10 carbon atoms formed by bonding R¹³ and R¹⁴ to each other, a group in which R¹³ and R¹⁴ are bonded to each other to form a 5-membered ring or a 6-membered ring together with the sulfur atom to which R¹³ and R¹⁴ are bonded, particularly, a group forming a 5-membered ring (tetrahydrothiophene ring) is preferable.

Some or all hydrogen atoms of the divalent group may be substituted with at least one group selected from the group consisting of a hydroxy group, a carboxy group, a cyano group, a nitro group, an alkoxy group, an alkoxyalkyl group, an alkoxycarbonyl group, and an alkoxycarbonyloxy group. Examples of the alkoxy group, the alkoxyalkyl group, the alkoxycarbonyl group, and the alkoxycarbonyloxy group include the groups exemplified in the above section of the phenyl group.

In the formula (B1), R¹³ and R¹⁴ are preferably a methyl group, an ethyl group, a phenyl group, a 4-methoxyphenyl group, a 1-naphthyl group, and a group in which R¹³ and R¹⁴ are bonded to each other to form a tetrahydrothiophene ring together with the sulfur atom to which R¹³ and R¹⁴ are bonded.

Examples of the cation in the compound represented by the formula (B1) include a triphenylsulfonium cation, a 4-phenylthiophenyldiphenylsulfonium cation, a tri-1-naphthylsulfonium cation, a tri-tert-butylphenylsulfonium cation, a 4-fluorophenyl-diphenylsulfonium cation, a di-4 fluorophenyl-phenylsulfonium cation, a tri-4-fluorophenylsulfonium cation, a 4-cyclohexylphenyl-diphenylsulfonium cation, a 4-methanesulfonylphenyl-diphenylsulfonium cation, a 4-cyclohexanesulfonyl-diphenylsulfonium cation, a 1-naphthyldimethylsulfonium cation, a 1-naphthyldiethylsulfonium cation, a 1-(4-hydroxynaphthyl)dimethylsulfonium cation, a 1-(4-methylnaphthyl)dimethylsulfonium cation, a 1-(4-methylnaphthyl)diethylsulfonium cation, a 1-(4-cyanonaphthyl)dimethylsulfonium cation, a 1-(4-cyanonaphthyl)diethylsulfonium cation, a 1-(3,5-dimethyl-4 hydroxyphenyl)tetrahydrothiophenium cation, a 1-(4-methoxynaphthyl)tetrahydrothiophenium cation, a 1-(4-ethoxynaphthyl)tetrahydrothiophenium cation, a 1-(4-n-propoxynaphthyl) tetrahydrothiophenium cation, a 1-(4-n-butoxynaphthyl) tetrahydrothiophenium cation, a 2-(7-methoxynaphthyl)tetrahydrothiophenium cation, a 1-(4,7-di-n-butoxynaphthyl)tetrahydrothiophenium cation, a 1-(2,7-di-n-butoxynaphthyl)tetrahydrothiophenium cation, a 2-(7-ethoxynaphthyl)tetrahydrothiophenium cation, a 2-(7-n-propoxynaphthyl)tetrahydrothiophenium cation, and a 2-(7-n-butoxynaphthyl)tetrahydrothiophenium cation, and also include cations represented by formulae below.

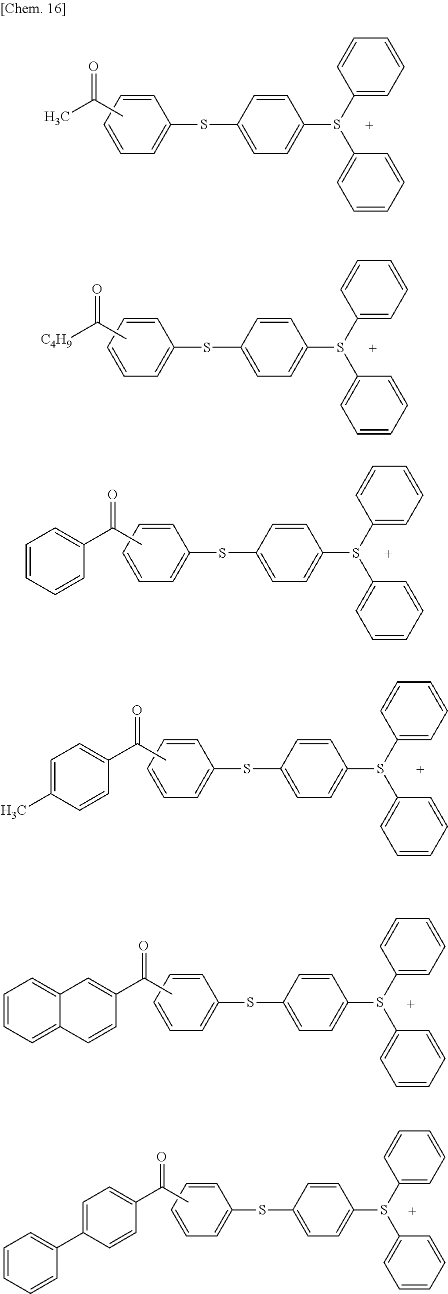

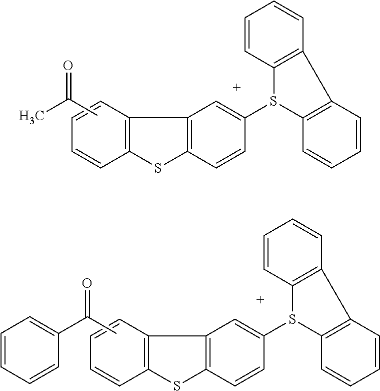

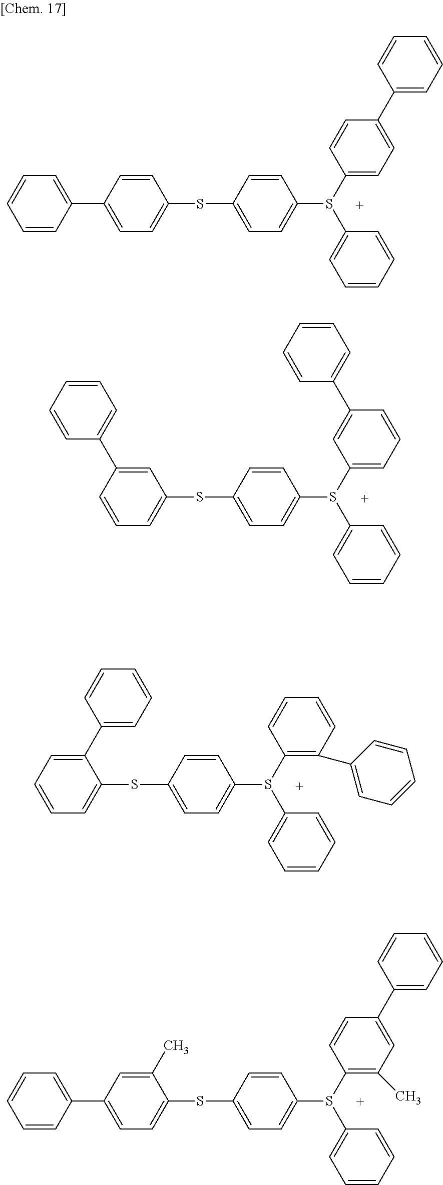

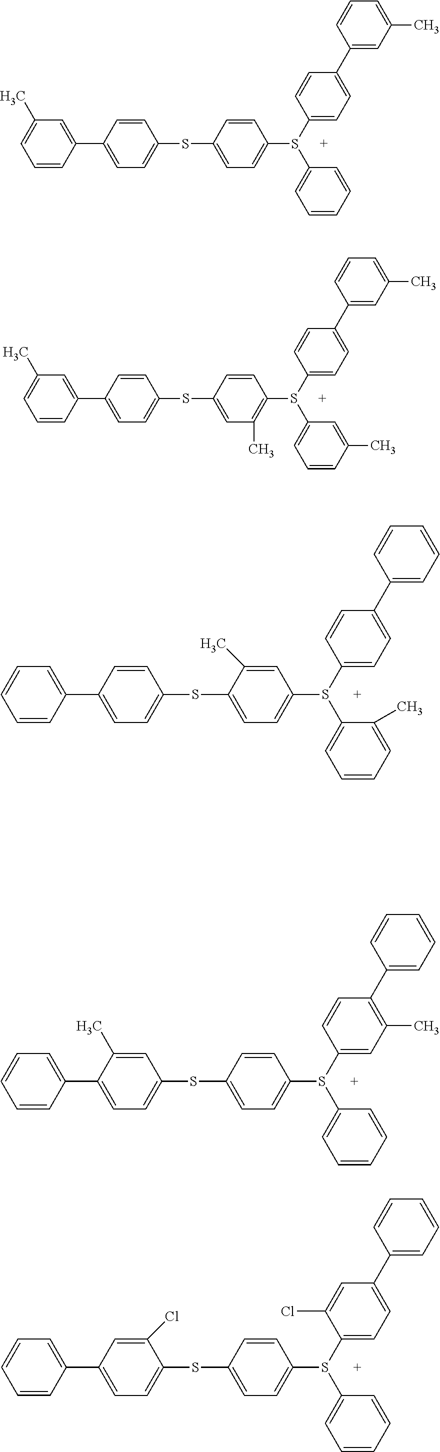

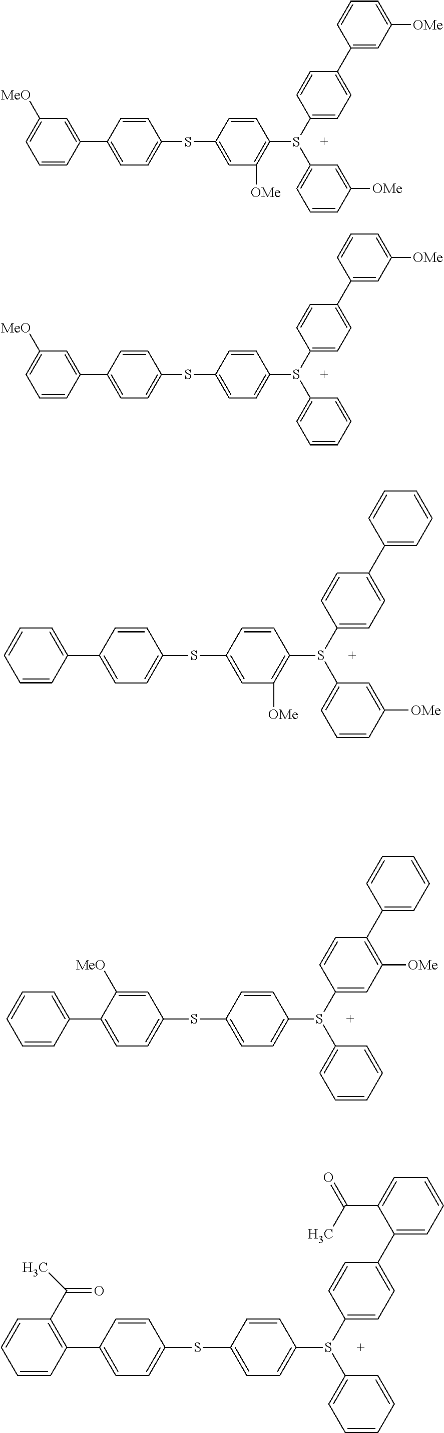

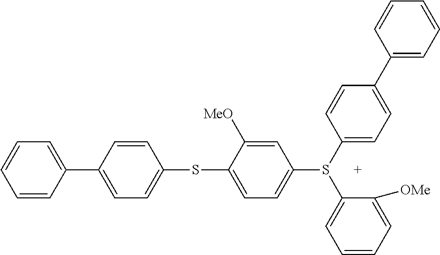

In the formula (b-1), —CₚH_{q}Fᵣ—is a fluoroalkylene group having p carbon atoms, and may be linear or branched. p is preferably 1, 2, 4, or 8, and r is preferably an integer of 2 or more. q may be 0.

In the formulae (b-1) and (b-2), the hydrocarbon group having 1 to 12 carbon atoms represented by R¹⁵ is preferably an alkyl group having 1 to 12 carbon atoms, a cycloalkyl group or a bridged alicyclic hydrocarbon group having 4 to 12 carbon atoms, or an aromatic hydrocarbon group having 6 to 12 carbon atoms.

In the formulae (b-3) and (b-4), examples of the fluorine-substituted alkyl group having 1 to 10 carbon atoms represented by R¹⁶ to R²⁰ include a trifluoromethyl group, a pentafluoroethyl group, a heptafluoropropyl group, a nonafluorobutyl group, a dodecafluoropentyl group, and a perfluorooctyl group.

Examples of the divalent fluorine-substituted alkylene group having 2 to 10 carbon atoms formed by bonding R¹⁶ and R¹⁷ to each other in the formula (b-3) and formed by bonding two of R¹⁸ to R²⁰ to each other in the formula (b-4) include a tetrafluoroethylene group, a hexafluoropropylene group, an octafluorobutylene group, a decafluoropentylene group, and an undecafluorohexylene group.

As the anion in the compound represented by the formula (B1), a trifluoromethanesulfonate anion, a perfluoro-n-butanesulfonate anion, a perfluoro-n-octanesulfonate anion, a 2-(bicyclo[2.2.1]hepta-2-yl)-1,1,2,2-tetrafluoroethanesulfonate anion, a 2-(bicyclo[2.2.1]hepta-2-yl)-1,1-difluoroethanesulfonate anion, and a 1-adamantyl sulfonate anion are preferable.

The photoacid generator (B) containing a compound represented by the formula (B1) can be formed of, for example, a combination of a cation and an anion exemplified above. However, the combination is not particularly limited. In the photosensitive resin composition of the present invention, as the compound represented by the formula (B1) in the photoacid generator (B), one type may be used alone or two or more types may be used in admixture.

The photoacid generator (B) preferably contains a compound represented by the formula (B1), and when the photoacid generator represented by the formula (B1) is contained, the content ratio thereof is 1 to 100 mol %, and preferably 5 to 100% with respect to 100 mol % of the photoacid generator (B).

The photoacid generator (B) may be composed only of the compound represented by the formula (B1), may be composed only of another photoacid generator, or may be composed of the compound represented by the formula (B1) and another photoacid generator. Examples of the another photoacid generator include an onium salt compound having a structure other than the formula (B1), a halogen-containing compound, a sulfone compound, and a sulfonic acid compound. Specific examples thereof include the following.

Examples of the onium salt compound having a structure other than the formula (B1) include an iodonium salt, a sulfonium salt having a structure other than the formula (B1), a phosphonium salt, a diazonium salt, and a pyridinium salt.

Examples of the halogen-containing compound include a haloalkyl group-containing hydrocarbon compound and a haloalkyl group-containing heterocyclic compound.

Examples of the sulfone compound include β-ketosulfone, β-sulfonylsulfone, and α-diazo compounds of these compounds.

Examples of the sulfonic acid compound include an alkylsulfonate ester, an alkylsulfonic acid imide, a haloalkylsulfonate ester, an arylsulfonate ester, and an iminosulfonate.

As such another photoacid generator, one type can be used alone or two or more types can be used in admixture.

In the photosensitive resin composition containing such a photoacid generator (B), a sufficient acid strength is obtained for causing a deprotection reaction of the acid-dissociable group contained in the polymer (A), and a good resist pattern shape can be obtained by applying an anion having an appropriate size.

As the photoacid generator (B), as described above, a compound that is decomposed by the action of light to produce a compound acting as an acid can be used, and preferably, a compound that is represented by the formula (B1) and is decomposed by the action of light to produce a compound acting as an acid can be used. In the present invention, as the photoacid generator (B), one type of such photoacid generators may be used alone or two or more types thereof may be used in combination. Preferably, the photoacid generator (B) desirably contains a compound represented by the formula (B1). Specifically, one type of compound represented by the formula (B1) may be used alone, or two or more types of compounds represented by the formula (B1) may be used in combination, or one or more types of other photoacid generators described above may be used in combination with the compound represented by the formula (B1).

The content of the photoacid generator (B) in the photosensitive resin composition of the present invention is usually 0.1 to 20 parts by mass, preferably 0.3 to 15 parts by mass, and more preferably 0.5 to 10 parts by mass with respect to 100 parts by mass of the polymer (A). When the content of the photoacid generator (B) is within the above range, a resist pattern film having more excellent resolution tends to be obtained.

### [Organic Solvent (C)]

The photosensitive resin composition of the present invention contains an organic solvent (C) containing 3-ethoxyethyl propionate (ethyl 3-ethoxypropionate).

In the photosensitive resin composition of the present invention, the organic solvent (C) containing 3-ethoxyethyl propionate is contained, and therefore the dryability after application is excellent, bubble entrainment is less likely to occur, and application bubbles contained in the resulting resist coating film are sufficiently prevented.

The organic solvent (C) according to the present invention may be only 3-ethoxyethyl propionate, or may contain one or more types of organic solvents other than 3-ethoxyethyl propionate together with 3-ethoxyethyl propionate as long as the effects are not impaired.

The content ratio of 3-ethoxyethyl propionate in the organic solvent (C) is usually 20 to 100 mass %, preferably 40 to 100 mass %, and more preferably 60 to 100 mass %. When the organic solvent (C) contains 3-ethoxyethyl propionate within such a range, the photosensitive resin composition has excellent dryability after application, and an excellent effect that application bubbles contained in the resulting resist coating film are sufficiently prevented is sufficiently obtained.

In addition, for the purpose of, for example, regulating the viscosity of the photosensitive resin composition according to the intended coating film thickness, adjusting compatibility with various components, or imparting crack resistance in order to counteract stress when a plated shaped article is produced, the content ratio of 3-ethoxyethyl propionate in the organic solvent (C) is set within a range that does not impair the effects of the present invention, for example, within a range of 20 to 80 mass %, preferably 30 to 70 mass %, more preferably 40 to 60 mass %, so that the organic solvent (C) can contain an organic solvent other than 3-ethoxyethyl propionate.

As the organic solvent (another organic solvent) other than 3-ethoxyethyl propionate, an organic solvent conventionally known as a solvent of the photosensitive resin composition can be used without particular limitation.

Examples of the another organic solvent particularly for the purpose of regulating the viscosity of the photosensitive resin composition according to the coating film thickness and adjusting the compatibility with components include alcohol solvents such as ethylene glycol monomethyl ether (boiling point: 124 to 125° C.), ethyl lactate (boiling point: 151 to 155° C.), propylene glycol monomethyl ether (boiling point: 121° C.), 2,4-dimethyl-3-pentanol (boiling point: 139° C.), 2-hexanol (boiling point: 146° C.), and 4-methyl-2-pentanol (boiling point: 132° C.); ester solvents such as ethyl 2-hydroxypropionate (boiling point: 154° C.), ethyl 2-hydroxy-2-methylpropionate, methyl acetoacetate (boiling point: 169 to 170° C.), 3-methoxybutyl acetate (3MBA, boiling point 171° C.), butyl propionate (boiling point: 146° C.), isobutyl methacrylate (boiling point: 155° C.), allyl methacrylate (boiling point: 147° C.), and isobutyl isobutyrate (boiling point: 147° C.); ketone solvents such as methyl amyl ketone (boiling point: 151° C.), cyclohexanone (boiling point: 155.6° C.), 3-heptanone (boiling point: 147° C.), and 4-heptanone (boiling point: 144° C.); alkylene glycol dialkyl ethers such as diethylene glycol dimethyl ether, diethylene glycol diethyl ether (boiling point: 162° C.), diethylene glycol di-n-propyl ether, and dipropylene glycol dimethyl ether; alkylene glycol monoalkyl ether acetates such as ethylene glycol monomethyl ether acetate (boiling point: 145° C.), ethylene glycol monoethyl ether acetate (boiling point: 145° C.), propylene glycol monomethyl ether acetate (PGMEA, boiling point 146° C.), propylene glycol monoethyl ether acetate, and propylene glycol mono-n-propyl ether acetate. In addition, examples of the another solvent particularly for the purpose of imparting crack resistance to stress when a plated shaped article is produced include ethylene glycol monoethyl ether (boiling point: 196° C.), diethylene glycol (boiling point: 244° C.), diethylene glycol monoethyl ether (boiling point: 202° C.), and γ-butyrolactone (boiling point: 204° C.).

In the present invention, the another organic solvent to be used in combination is desirably an organic solvent having a boiling point of preferably 120° C. or higher, more preferably a boiling point of 120° C. to 180° C., and still more preferably a boiling point of 140 to 160° C., and a small amount of a solvent having a boiling point of 190 to 250° C. can also be used in combination for the purpose of imparting crack resistance to stress when a plated shaped article is produced. Use of such an organic solvent prevents vaporization of the organic solvent in the photosensitive resin composition at a high speed and can provide a resin composition that is less likely to be thickened during operation and has a long pot life, and also avoids vaporization of the solvent at a high speed after application, and can improve in-plane uniformity of the coating film thickness in addition to not interfering with an effect of preventing generation of application bubbles.

Among other organic solvents having a boiling point in such a range, propylene glycol methyl ether acetate (PGMEA), 3-methoxybutyl acetate (3MBA), 3-methoxymethyl propionate, diethylene glycol methyl ether, 2-heptanone, and ethyl lactate are preferable, and propylene glycol methyl ether acetate and 3-methoxybutyl acetate are more preferable because these solvents are easily availability, and when being used in combination with 3-ethoxyethyl propionate, the effect of preventing generation of application bubbles of a resist coating film obtained from the photosensitive resin composition is hardly impaired. Either one of propylene glycol methyl ether acetate and 3-methoxybutyl acetate may be used, or both may be used in any ratio.

The photosensitive resin composition of the present invention exhibits an unexpected remarkable effect that a film due to drying is less likely to be formed on the surface, and the organic solvent is easy to evaporate in a heating step after formation of a coating film by the incorporation of 3-ethoxyethyl propionate in the organic solvent (C) although 3-ethoxyethyl propionate is a solvent having a high boiling point of 170° C. Therefore, when the photosensitive resin composition of the present invention is used, the photosensitive resin composition is excellent in followability even when a coating film is provided on a substrate having a step, bubble entrainment is less likely to occur, and a film due to drying (dry film) is less likely to be formed. Therefore, air bubbles are less likely to be confined in a dry film, and even when a resin coating film having a large film thickness is formed, application bubbles can be remarkably prevented, and a resist coating film in which generation of application bubbles is sufficiently prevented can be produced.

As to why a coating film having fewer application bubble defects can be formed with 3-ethoxyethyl propionate as compared with other high-boiling point solvents, the inventor has focused on the evaporation rate thereof. For example, 3-ethoxyethyl propionate is compared with 3-methoxybutyl acetate, which is a conventionally known high-boiling point solvent. The boiling point of 3-ethoxyethyl propionate is 170° C. and the boiling point of 3-methoxybutyl acetate is 172° C., which show values very close to each other. When the inventors focused on the evaporation rate when a photosensitive resin composition was prepared to form a coating film, it was found that the evaporation rate of 3-ethoxyethyl propionate was faster. From this, it is presumed that in the case of 3-methoxybutyl acetate having a lower evaporation rate, a dry film is likely to be formed on the surface of the coating film, a solvent is likely to be retained inside the film, and bubbles generated therein cannot escape to the outside of the film, which tends to cause application bubble defects. Meanwhile, it is presumed that in the case of 3-ethoxyethyl propionate, the formation of a dry film on the coating surface was prevented, and in addition to the discharge of the solvent enclosed in the coating film, generated bubbles inside the film could also be discharged to the outside of the film in the heating step.

The content ratio of the organic solvent in the photosensitive resin composition of the present invention is usually 70 mass % or less, preferably 40 to 60 mass %, and more preferably 45 to 55 mass %. In the present invention, when the solid content concentration (concentration of components excluding a volatile organic solvent) in the photosensitive resin composition is 30 mass % or more, a resin coating film having a large film thickness can be easily formed.

### [Quencher (D)]

The photosensitive resin composition of the present invention can further contain a quencher (D) in addition to the polymer (A), the photoacid generator (B), and the organic solvent (C) described above.

The quencher (D) is, for example, a component used for controlling diffusion of an acid generated by exposure from the photoacid generator (B) in the resin film, and, as a result, can improve the resolution of the present composition.

Examples of the quencher (D) include a basic compound and a compound that generates a base, and examples thereof include compounds described in JP 2011-029636 A, JP 2014-013381 A, JP 2015-526752 A, JP 2016-099483 A, and JP 2017-037320 A. These shall be described herein.

Examples of the quencher (D) include alkylamines such as n-hexylamine, n-heptylamine, di-n-butylamine, and triethylamine; aromatic amines such as aniline and 1-naphthylamine; alkanolamines such as triethanolamine; polyamino compounds such as ethylenediamine, 1,3-bis[1-(4-aminophenyl)-1-methylethyl]benzene, and polyethyleneimine; amide compounds such as formamide; urea compounds such as urea and methylurea; nitrogen-containing heterocyclic compounds such as imidazole and benzimidazole; and nitrogen-containing compounds having an acid-dissociable group such as N-(t-butoxycarbonyl)piperidine, N-(t-butoxycarbonyl)-4-hydroxypiperidine, N-(t-butoxycarbonyl)imidazole, N-(t-butoxycarbonyl)benzimidazole, and N-(t-butoxycarbonyl)-2-phenylbenzimidazole.

The present composition can contain one type or two or more types of quenchers (D).

The content of the quencher (D) in the present composition is usually 0.001 to 10 parts by mass, and preferably 0.01 to 5 parts by mass with respect to 100 parts by mass of the polymer (A).

### [Another Component]

The photosensitive resin composition of the present invention may contain another component other than the polymer (A), the photoacid generator (B), and the organic solvent (C) described above as long as the object of the present invention is not impaired. Examples of the another component include resin components other than the polymer (A), and various additives.

Examples of the another component include, for example, a surfactant that exhibits an action of improving coating applicability, defoamability of the photosensitive resin composition, a sensitizer that absorbs exposure light to improve the acid generation efficiency of a photoacid generator, an alkali-soluble resin or a low molecular weight phenol compound that controls a dissolution rate of a resin film formed from the photosensitive resin composition in an alkaline developer, an ultraviolet absorber that blocks a photoreaction due to wraparound of scattered light to an unexposed portion during exposure, a thermal polymerization inhibitor that enhances the storage stability of the photosensitive resin composition, an additive that acts on a Cu surface to prevent a quenching action of the Cu surface so as to be able to improve the trailing shape of the resist bottom, and addition thereto, an antioxidant, an adhesion aid, and an inorganic filler. In particular, when the photosensitive resin composition of the present invention is used as a template for a plated shaped article, a thiol group-containing compound can be added as an additive that acts on a Cu surface to prevent a quenching action of the Cu surface so as to be able to improve the trailing shape of the resist bottom.

### [Production of Photosensitive Resin Composition]

The photosensitive resin composition of the present invention can be produced by uniformly mixing the respective components described above. In addition, in order to remove foreign substances, after the respective components are uniformly mixed, the obtained mixture can be filtered with a filter.

### <Method for Producing Resist Pattern Film>

A method for producing a resist pattern film of the present invention includes a step (1) of applying the photosensitive resin composition onto a substrate to form a resin coating film, a step (2) of exposing the resin coating film to light, and a step (3) of developing the resin coating film after exposure.

### [Step (1)]

The Step (1) is a step of applying the photosensitive resin composition onto a substrate to form a resin coating film. As the substrate, a substrate having a metal film is usually used, and the photosensitive resin composition is applied onto the metal film of the substrate.

Examples of the substrate include a semiconductor substrate and a silicon substrate having a metal film on a surface thereof. The shape of the substrate is not particularly limited, and examples of the surface shape include a flat plate shape and an uneven shape, and examples of the shape of the substrate include a circular shape and a square shape. The size of the substrate is not limited.

Examples of the metal film include films of metals such as aluminum, copper, silver, gold, and palladium, and alloys containing two or more of the metals, and a copper film, that is, a film containing copper and/or a copper alloy is preferable. The thickness of the metal film is usually 100 to 10,000 Å, and preferably 500 to 2,000 Å. The metal film is usually provided on the surface of the substrate. The metal film can be formed by a method such as a sputtering method.

The resin coating film is usually formed by applying the present composition onto a metal film of a substrate having the metal film. Examples of the method for applying the present composition include a spin coating method, a roll coating method, a screen printing method, and an applicator method, and among these methods, a spin coating method and a screen printing method are preferable.

After applying the present composition, a heat treatment can be performed for the applied present composition for the purpose of volatilizing the organic solvent, for example. The conditions of the heat treatment is usually 50 to 200° C. for 0.5 to 20 minutes.

The thickness of the resin coating film is usually 1 to 100 μm, and preferably 5 to 80 μm, but in the present invention, it is preferable to produce a resin coating film having a large film thickness, and for example, the thickness of the resin coating film can be set to 20 μm or more, preferably 25 to 100 μm, and more preferably 30 to 80 μm.

In the present invention, the photosensitive resin composition to be applied contains 3-ethoxyethyl propionate, and therefore it can be prevented that only the surface of the coating film is quickly dried to form a film, so that volatilization of the organic solvent remaining in the coating film is prevented, and generation of application bubbles therein can be inhibited.

### [Step (2)]

In the step (2), the resin coating film formed in the step (1) is exposed to light.

The exposure is usually selectively performed on the resin coating film by equal magnification projection exposure or reduction projection exposure via a photomask having a predetermined mask pattern. Examples of the exposure light include ultraviolet light or visible light having a wavelength of 150 to 600 nm, preferably 200 to 500 nm. Examples of the light source of the exposure light include a low-pressure mercury lamp, a high-pressure mercury lamp, an ultra-high-pressure mercury lamp, a metal halide lamp, and a laser. The exposure amount can be appropriately selected depending on the type of exposure light, the type of photosensitive resin composition, and the thickness of the resin coating film, and is usually 100 to 20,000 mJ/cm².

After exposure of the resin coating film, a heat treatment can be performed for the resin coating film before development. The conditions of the heat treatment are usually 70 to 180° C. for 0.5 to 10 minutes. By the heat treatment, the dissociation reaction of the acid-dissociable group by the acid in the polymer (A) can be promoted.

### [Step (3)]

In the step (3), the resin coating film exposed in the step (2) is developed to form a resist pattern film. The development is usually performed using an alkaline developer. Examples of the developing method include a shower method, a spray method, an immersion method, a liquid filling method, and a paddle method. The development conditions are usually 10 to 30° C. for 1 to 30 minutes.

Examples of the alkaline developer include an aqueous solution containing one type or two or more types of alkaline substances. Examples of the alkaline substance include sodium hydroxide, potassium hydroxide, sodium carbonate, sodium silicate, ammonia water, ethylamine, n-propylamine, diethylamine, triethylamine, monoethanolamine, diethanolamine, triethanolamine, tetramethylammonium hydroxide, tetraethylammonium hydroxide, choline, pyrrole, and piperidine. The concentration of the alkaline substance in the alkaline developer is usually 0.1 to 10 mass %. The alkaline developer can further contain, for example, an organic solvent such as methanol or ethanol and/or a surfactant.

The resist pattern film formed by development can be washed with water, for example. Thereafter, the resist pattern film can be dried using an air gun or a hot plate.

As described above, it is possible to form a resist pattern film to serve as a mold for forming a plated shaped article on the metal film of the substrate while failures and defects due to formation of application bubbles are prevented, and thus a plating substrate having a resist pattern film (mold) on a metal film is obtained. The thickness of the resist pattern film is usually 1 to 100 μm, and preferably 5 to 80 μm, but in the present invention, it is preferable to produce a resist pattern film having a large film thickness, and for example, the thickness can be set to 20 μm or more, preferably 25 to 100 μm, and more preferably 30 to 80 μm.

As the shape of the opening of the resist pattern film, a shape suitable for the type of plated shaped article can be selected. When the plated shaped article is wiring, the shape of the pattern is, for example, a line-and-space pattern, and when the plated shaped article is a bump having a circular or polygonal columnar shape, the shape of the resist pattern opening is, for example, a hole pattern having a circular or cubic shape.

Use of a plating substrate having a resist pattern film (mold) in which formation of application bubbles is prevented and failures and defects are prevented enables the production of a plated shaped article accurately having a desired pattern shape.

### [Method for Producing Plated Shaped Article]

The method for producing a plated shaped article of the present invention includes a step of performing a plating treatment on the substrate using a resist pattern film produced by the method for producing a resist pattern film of the present invention as a mask. That is, a plated shaped article is formed by a plating treatment on an opening (a portion removed by development) defined by the resist pattern film using the resist pattern film as a mold.

Examples of the plated shaped article include a bump and wiring. The plated shaped article is made of, for example, a conductor such as copper, gold, or nickel, and the thickness of the plated shaped article varies depending on the application. The film thickness of the resist pattern to serve as a mold can be changed according to the required thickness of the plated shaped article.

### Step of Performing Plating Treatment

Examples of the plating treatment include a plating solution treatment using a plating solution. Examples of the plating solution include a copper plating solution, a gold plating solution, a nickel plating solution, a solder plating solution, and a tin-silver plating solution.

Specific examples of the plating treatment include wet plating treatments such as an electroplating treatment, an electroless plating treatment, and a hot-dip plating treatment. When bumps or wiring is formed in processing at a wafer level, bumps or wiring is usually formed by an electroplating method.

### Other Steps

The method for producing a plated shaped article of the present invention may further include a step of removing the resist pattern film after the step of performing a plating treatment. This step is specifically a step of stripping and removing the remaining resist pattern film, and examples thereof include a method in which a substrate having a resist pattern film and a plated shaped article is immersed in a stripping liquid containing a basic compound such as tetramethylammonium hydroxide, dimethyl sulfoxide, or N,N-dimethylformamide.

The method for producing a plated shaped article of the present invention may further include a step of removing the metal film in a region other than the region where the plated shaped article is formed, for example, by a method such as a wet etching method.

### EXAMPLES

Hereinafter, the present invention will be described more specifically based on examples, but the present invention is not limited to these examples.

### Synthesis of Polymer

Monomers used in the synthesis of each polymer are shown below. In the following synthesis examples, unless otherwise specified, the unit: parts by mass means a value when the total mass of monomers used is taken as 100 parts by mass, and mol % means a value when the total number of moles of monomers used is taken as 100 mol %.

### <Monomers Used for Synthesis of Polymers>

In the synthesis of the following polymers, compounds represented by formulae below were used as monomers. Each of these compounds is a commercially available product.

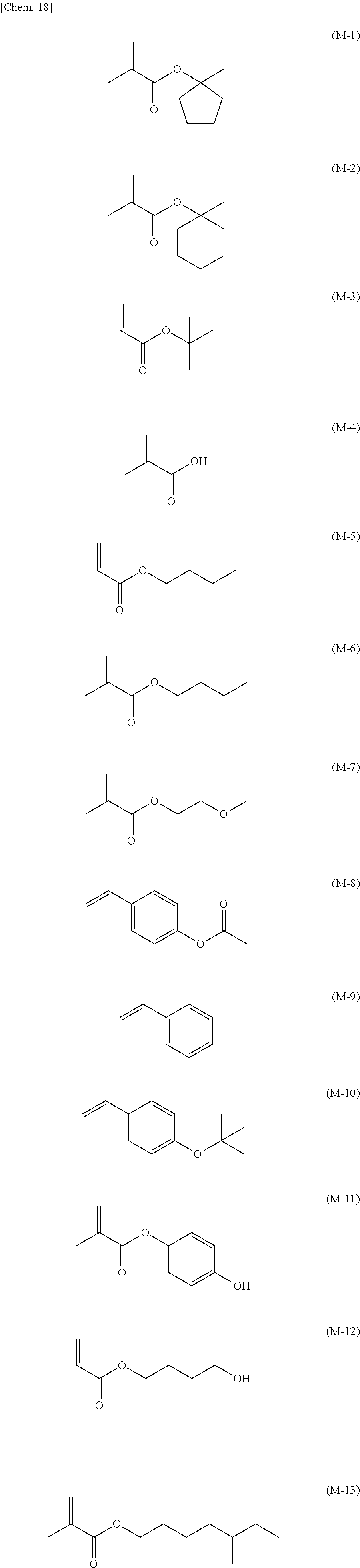

### Synthesis Example 1

### (Synthesis of Polymer (A-1))

In a flask equipped with a nitrogen-substituted dry ice/methanol reflux device, dimethyl 2,2′-azobis(isobutyrate) as a polymerization initiator was placed in an amount of 0.8 mol % with respect to 100 mol % of the total monomers, and diethylene glycol ethyl methyl ether was used as a polymerization solvent, and the mixture was stirred until the polymerization initiator was dissolved. To this solution, a monomer (M-1), a monomer (M-3), a monomer (M-5), and a monomer (M-11) were added in a molar ratio of 10/25/15/50, and the mixture was started to be gently stirred and heated to 80° C. Thereafter, polymerization was performed at 80° C. for 6 hours.

After completion of the polymerization reaction, the reaction product was dropped into a large amount of cyclohexane and solidified. This solidified product was washed with water, and the solidified product was redissolved in tetrahydrofuran of the same weight as the solidified product, and then the obtained solution was dropped into a large amount of cyclohexane and solidified again. This redissolution and solidification operations were performed 3 times in total, and then the obtained solidified product was vacuum-dried at 40° C. for 48 hours to obtain a desired polymer (A-1). The configuration of the obtained polymer (A-1) (the types of structural units contained in the polymer and the molar ratio thereof) is shown in a formula below.

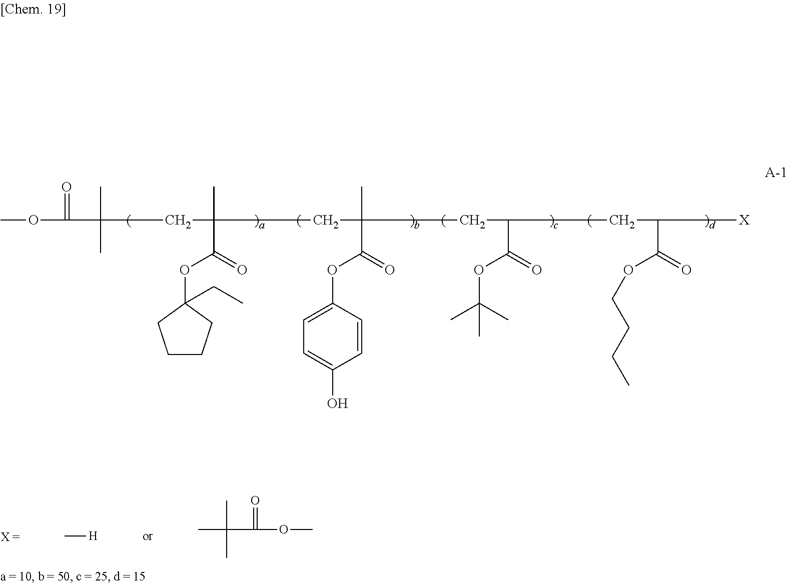

### Synthesis Examples 2 and 3

### (Synthesis of Polymers (A-2) and (A-3))

Polymers (A-2) and (A-3) were obtained by polymerized in the same manner as in Synthesis Example 1 except that the types of monomers used and the molar ratio of the monomers in each polymer were changed as shown in Table 1. The configurations (the types of structural units contained in the polymers and the molar ratios thereof) of the obtained polymers (A-2) and (A-3) are shown in formulae below, respectively.

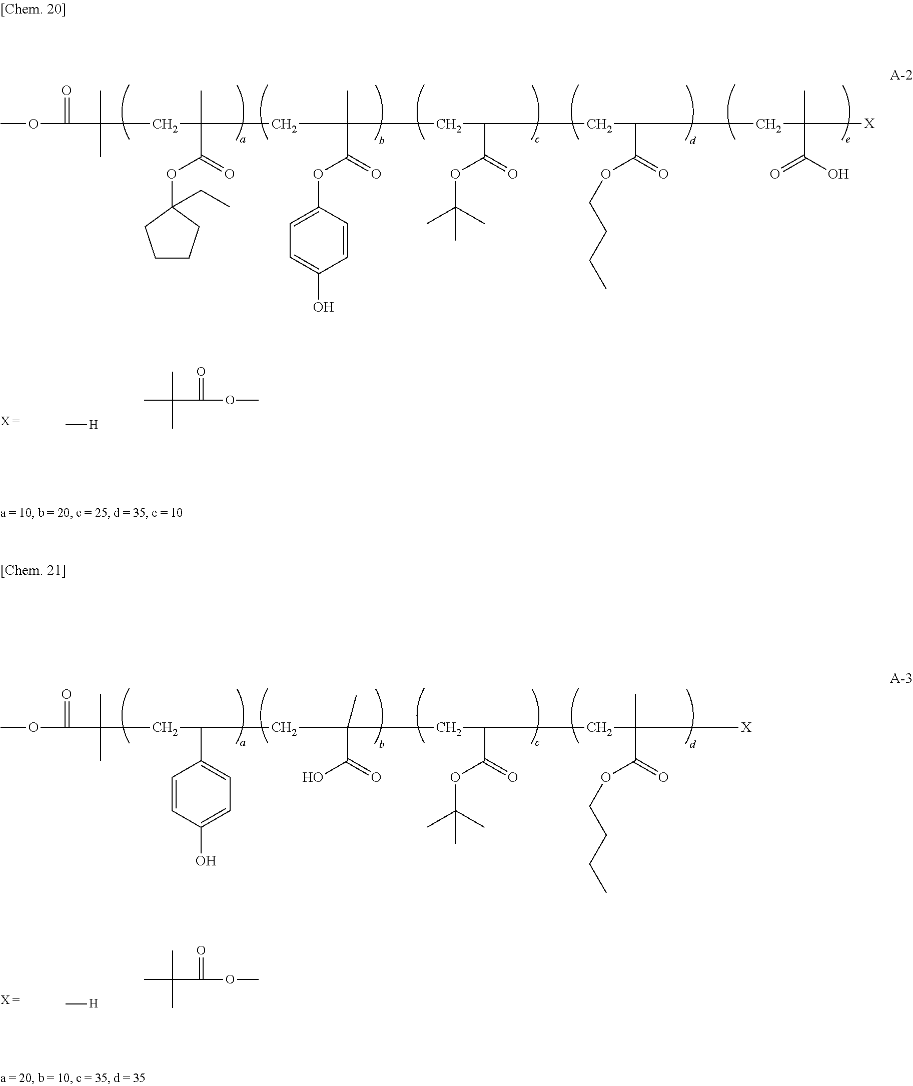

### Synthesis Example 4

### (Synthesis of Polymer (A-4))

In a flask equipped with a nitrogen-substituted dry ice/methanol reflux device, dimethyl 2,2′-azobis(isobutyrate) as a polymerization initiator was placed in an amount of 0.7 mol % with respect to 100 mol % of the total monomers, and diethylene glycol ethyl methyl ether was used as a polymerization solvent, and the mixture was stirred until the polymerization initiator was dissolved. To this solution, a monomer (M-2), a monomer (M-3), a monomer (M-7), a monomer (M-8), and a monomer (M-11) were added in a molar ratio of 10/20/20/30/20, and the mixture was started to be gently stirred and heated to 80° C. Thereafter, polymerization was performed at 80° C. for 6 hours. After completion of the polymerization reaction, the reaction product was dropped into a large amount of cyclohexane and solidified, and then separated by filtration.

A white powder separated by filtration was washed twice with hexane, then separated by filtration, and dissolved in 1-methoxy-2-propanol. Subsequently, methanol, triethylamine, and ultrapure water were added thereto, and a hydrolysis reaction was performed at 70° C. for 6 hours with stirring. After completion of the reaction, the remaining solvent was distilled off, and the obtained solid was redissolved in acetone and dropped into water to solidify the polymer. This redissolution and solidification operations were performed 3 times in total, and then the obtained solidified product was vacuum-dried at 40° C. for 48 hours to obtain a desired polymer (A-4). The configuration of the obtained polymer (A-4) is shown in formula below.

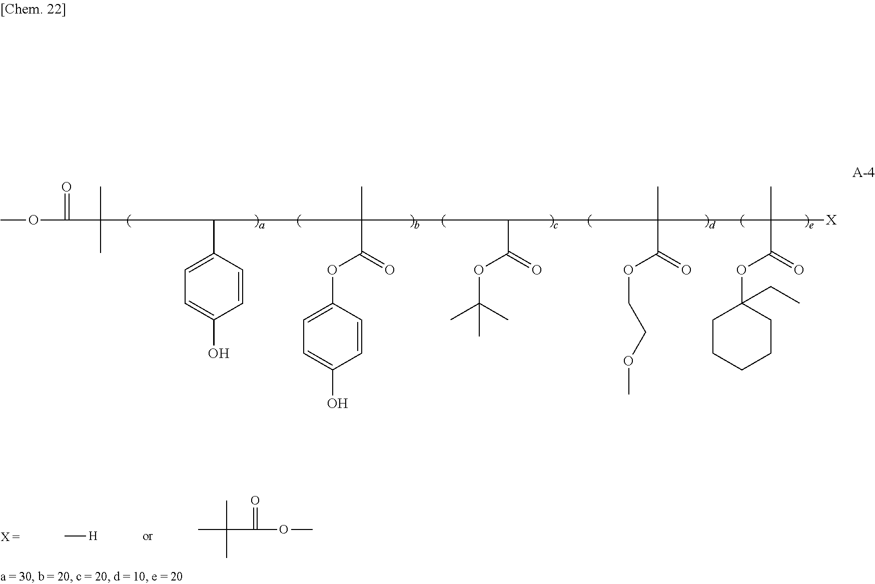

### Synthesis Example 5

A polymer (A-5) was obtained by polymerized in the same manner as in Synthesis Example 4 except that the molar ratio of monomers used in each polymer was changed as shown in Table 1. The configuration of the obtained polymer (A-5) (the molar ratio of structural units contained in the polymer) is as follows.
a=15, b=25, c=35, d=15, e=10

### Synthesis Example 6

(Synthesis of Polymer (a-1))

A novolac resin (m-cresol/3,5-xylenol=73/27) was obtained in the same manner as in the resin A(1) in JP H05-204158 A, [Synthesis Example 1]. This is referred to as a polymer (a-1).

### Synthesis Example 7

(Synthesis of Polymer (a-2))

A novolac resin (m-cresol/p-cresol=61/39) was obtained in the same manner as in the resin A(2) in JP H05-204158 A, [Synthesis Example 2]. This is referred to as a polymer (a-2).

### Synthesis Example 8

(Synthesis of Polymer (a-3))

A polymer (a-3) having a configuration represented by a formula below was obtained in the same manner as in JP 2006-282652 A, [Reference Example 1].

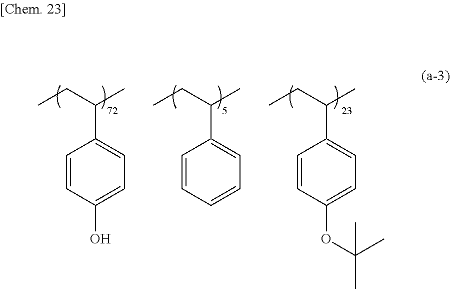

### Synthesis Example 9

(Synthesis of Polymer (a-4))

A polymer (a-4) having a configuration represented by a formula below was obtained by polymerized in the same manner as in Synthesis Example 1 except that the types of monomers used and the molar ratio of the monomers in each polymer were changed as shown in Table 1.

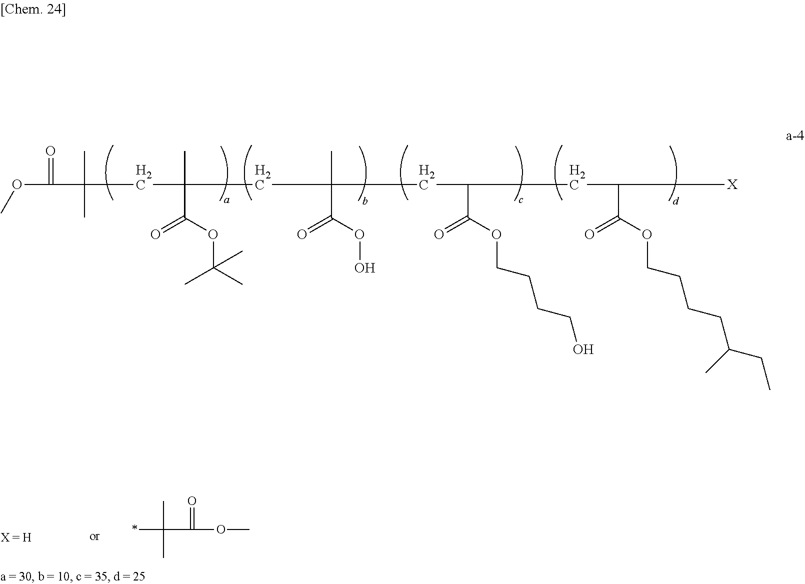

TABLE 1

| | | Monomer 1 | Monomer 2 | Monomer 3 | Monomer 4 | Monomer 5 | Monomer 6 |
|---|---|---|---|---|---|---|---|
| | | Type | Type | Type | Type | Type | Type |
| | Polymer | mol % | mol % | mol % | mol % | mol % | mol % |
| Synthesis | A-1 | M-1 | M-3 | M-11 | | M-5 | |
| Example 1 | | 10 | 25 | 50 | | 15 | |
| Synthesis | A-2 | M-1 | M-3 | M-11 | M-4 | M-5 | |
| Example 2 | | 10 | 25 | 20 | 10 | 35 | |
| Synthesis | A-3 | M-3 | | M-8 | M-4 | M-6 | |
| Example 3 | | 35 | | 20 | 10 | 35 | |
| Synthesis | A-4 | M-2 | M-3 | M-8 | M-11 | M-7 | |
| Example 4 | | 20 | 20 | 30 | 20 | 10 | |
| Synthesis | A-5 | M-2 | M-3 | M-8 | M-11 | M-7 | |
| Example 5 | | 10 | 35 | 15 | 25 | 15 | |
| Synthesis | a-3 | M-10 | | M-8 | | M-9 | |
| Example 8 | | 23 | | 72 | | 5 | |
| Synthesis | a-4 | M-3 | | | M-4 | M12 | M13 |
| Example 9 | | 30 | | | 10 | 35 | 25 |

It was checked by NMR that in all the structural units derived from the monomer M-8, the alkali-dissociable group was hydrolyzed to a phenolic hydroxy group.

### Respective Components

The respective components used in examples and comparative examples are shown below.

### <Photoacid Generator>

### (B-1):

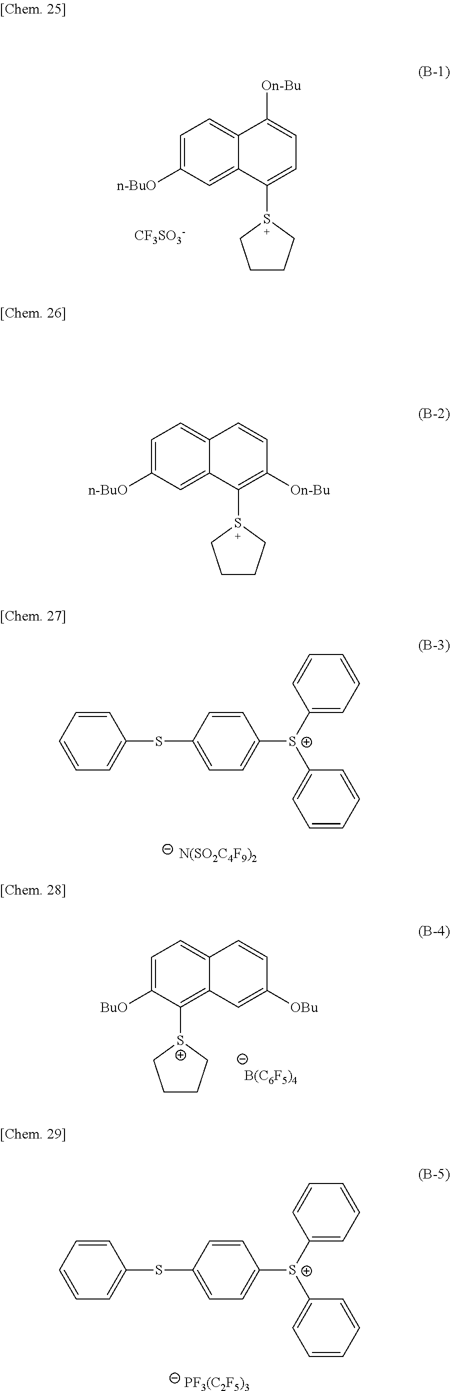

(b-1): a condensate of 1,1-bis(2-hydroxyphenyl)ethane (1 mol) and 1,2-naphthoquinonediazide-5-sulfonyl chloride (2.0 mol)

### <Solvent>

C-1: propylene glycol methyl ether acetate
C-2: methyl 3-methoxypropionate
C-3: ethyl lactate
C-4: 3-methoxybutyl acetate
C-5: diethylene glycol methyl ethyl ether

### <Quencher (Acid Diffusion Control Agent)>

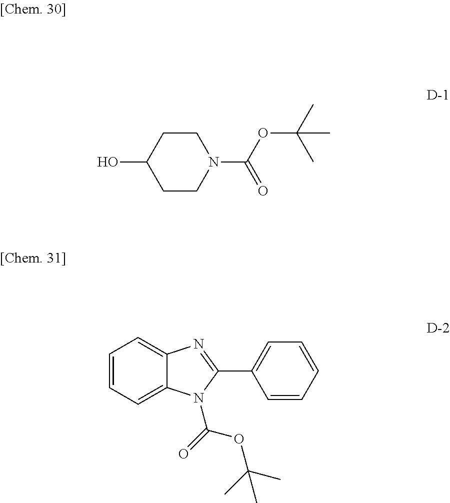 [SMILES: CC(C)(C)OC(=O)N1CCC(O)CC1 ; CC(C)(C)OC(=O)n1c(-c2ccccc2)nc2ccccc21]

### <Surfactant>

F-1: “NBX-15”, manufactured by NEOS COMPANY LIMITED

### <Additive>

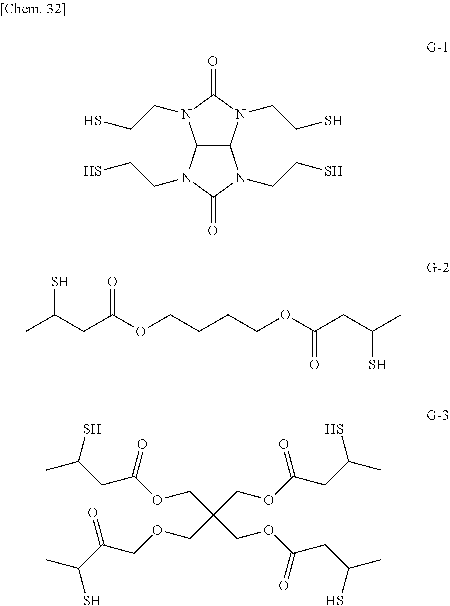

### Example 1

### <Preparation of Photosensitive Resin Composition>

In a mixed solvent containing components shown in Table 2 below, 47 parts by mass of the polymer (A-1), 1.5 parts by mass of the photoacid generator (B-1), 0.10 parts by mass of the quencher (D-2), and 0.01 parts by mass of the surfactant (F-1) (trade name: “NBX-15”, manufactured by NEOS COMPANY LIMITED) were uniformly mixed so as to have a solid content concentration of 48.6 mass %, thereby preparing a photosensitive resin composition of Example 1.

### <Evaluation of Thick Film Coating Applicability and Application Bubble Defects>

A resin film having a film thickness of 70 μm was formed by applying the photosensitive resin composition obtained above onto a silicon wafer substrate having a step of 140 μm in width, 1 cm in pitch, and 10 μm in depth by spin coating using a coater/developer (product name “ACT-8”) manufactured by Tokyo Electron Limited and followed by heating at 150° C. for 5 minutes. Thick film coating applicability and application bubble defects were evaluated according to the following criteria. The evaluation results are shown in Table 3.

### [Thick Film Coating Applicability]

The thickness of the resin film on the silicon wafer was evaluated using Lambda Ace VM-2210 manufactured by SCREEN Semiconductor Solutions Co., Ltd.
O: The coating film thickness is 70 μm or more.
X: The coating film thickness does not reach 70 μm.

### [Application Bubble Defects]

The application bubbles of the resin film on the silicon wafer were visually counted and evaluated according to the following criteria.
OO: The number of application bubbles is 0 or more and 20 or less.
O: The number of application bubbles is more than 20 and 30 or less.
Δ: The number of application bubbles is more than 30 and 200 or less.
X: The number of application bubbles is more than 200.

### <Formation of Resist Pattern Film and Evaluation of Pattern Shape>

A resin film having a film thickness of 70 μm was formed by applying the photosensitive resin composition obtained above onto a copper sputtered film of a silicon wafer substrate provided with the copper sputtered film by spin coating using a coater/developer (product name “ACT-8”) manufactured by Tokyo Electron Limited and followed by heating at 145° C. for 300 seconds.

The resin film was exposed through a pattern mask using a stepper (model “NSR-i10D” manufactured by Nikon Corporation). The coating film after exposure was heated at 90° C. for 180 seconds, and then developed by immersion in a 2.38 mass % aqueous tetramethylammonium hydroxide solution for 2,400 seconds. Thereafter, the substrate was washed with flowing water and blown with nitrogen to form a resist pattern film of 40 μm square (pitch 80 μm) on the copper sputtered film of the substrate.

The resist pattern film was cut along a plane Z parallel to the square opening and passing through the center point, and the shape of the cross section was observed with an electron microscope. When the cross-sectional shape was rectangular, the pattern shape was evaluated as 0, when the opening at the bottom was wider than the opening at the pattern top and the film had a tapered shape, or when a crack occurred in the pattern, the pattern shape was evaluated as A, and when the pattern could not be formed up to the bottom, the pattern shape was evaluated as X. The evaluation results are shown in Table 3.

### <Evaluation of Shape of Plated Shaped Article>

A plated shaped article was produced by an electroplating treatment using the resist pattern film as a mold. As a pretreatment for an electroplating treatment, a treatment with oxygen plasma (output: 100 W, oxygen flow rate: 100 ml, processing time: 60 seconds) was performed. The patterned substrate after the pretreatment was immersed in 1 L of a copper plating solution (product name “MICROFAB SC-40”, manufactured by MacDermid Performance Solutions Japan K.K.), and an electroplating treatment was performed for 25 minutes by setting the plating bath temperature to 25° C. and the current density to 6 A/dm² to form copper plating.

Subsequently, the patterned substrate on which the copper plating was formed was immersed in 1 L of a nickel plating solution (product name “MICROFAB Ni200”, manufactured by Electroplating Engineers of Japan Ltd.), and an electroplating treatment was performed for 16 minutes by setting the plating bath temperature to 50° C. and the current density to 3 A/dm² to form nickel plating on the copper plating.

Subsequently, the patterned substrate on which the copper-nickel plating was formed was immersed in 1 L of a tin-silver plating solution (product name “UTB TS-140”, manufactured by Ishihara Chemical Co., Ltd.), and an electroplating treatment was performed for 10 minutes by setting the plating bath temperature to 25° C. and the current density to 3 A/dm² to form a tin-silver plated shaped article on the copper-nickel.

The state of the produced plated shaped article was observed with an electron microscope and evaluated according to the following evaluation criteria. The evaluation results are shown in Table 3 below.
O: A straight plated shaped article was formed for a base Cu substrate.
Δ: Although a plated shaped article was obtained, the straightness of the plating side wall was impaired due to resist swelling or pattern distortion.
X: A target resist pattern film cannot be formed due to application bubbles, for example, and a plated shaped article cannot be formed.

### Examples 2 to 14 and Comparative Examples 1 to 6

Photosensitive resin compositions of Examples 2 to 14 and Comparative Examples 1 to 6 were produced in the same manner as in Example 1 except that the respective components in Example 1 were changed to components and amounts shown in Table 2.

Subsequently, the evaluation of thick film coating applicability and application bubble defects, and the formation of a resist pattern film, the evaluation of a pattern shape and a shape of a plated shaped article were performed in the same manner as in Example 1 except that each of the obtained photosensitive resin compositions was used. The results are shown in Table 3.

TABLE 2

| | | Example | | | | | | | | | | |
|---|---|---|---|---|---|---|---|---|---|---|---|---|
| Component | Type | 1 | 2 | 3 | 4 | 5 | 6 | 7 | 8 | 9 | 10 | 11 |
| Polymer | A-1 | 47 | 46 | | | 45 | | 45 | | | | |
| | A-2 | | | | | | | | 44 | 44 | | |
| | A-3 | | | 46 | | | 44 | | | | | |
| | A-4 | | | | 22 | | | | | | | 22 |
| | A-5 | | | | | | | | | | 45 | |
| | a-1 | | | | | | | | | | | |
| | a-2 | | | | 22 | | | | | | | 22 |
| | a-3 | | | | | | | | | | | |
| | a-4 | | | | | | | | | | | |
| Photoacid | B-1 | 1.5 | | | | | | | | | 3 | |
| generator | B-2 | | 3 | | | 4 | | 4 | 4 | | | |
| | B-3 | | | 3 | 4 | | 4 | | | 4 | | 4 |
| | B-4 | | | | | | | | | | | |
| | B-5 | | | | | | | | | | | |
| | b-1 | | | | | | | | | | | |
| Quencher | D-1 | | 0.12 | | 0.04 | | 0.04 | | 0.12 | | 0.04 | |
| | D-2 | 0.10 | | 0.03 | | 0.15 | | 0.15 | | 0.04 | | 0.04 |
| Surfactant | F-1 | 0.01 | 0.01 | 0.01 | 0.01 | 0.01 | 0.01 | 0.01 | 0.01 | 0.01 | 0.01 | 0.01 |
| Additive | G-1 | | 0.3 | | | | | 0.3 | | | 0.3 | |
| | G-2 | | | | 0.3 | | | | 0.3 | | | 0.3 |
| | G-3 | | | | | | 0.3 | | | 0.3 | | |
| 3-Ethoxyethyl | | 80 | 100 | 60 | 50 | 20 | 70 | 35 | 35 | 35 | 70 | 50 |
| propionate | | | | | | | | | | | | |
| Another | C-1 | 20 | | | | | | 65 | 65 | 65 | 30 | |
| solvent | C-2 | | | 40 | | | | | | | | |
| | C-3 | | | | 50 | | | | | | | |
| | C-4 | | | | | 80 | | | | | | 50 |
| | C-5 | | | | | | 30 | | | | | |

| | | | | | | | | | | | |
|---|---|---|---|---|---|---|---|---|---|---|---|
| Solid content | 48.6 | 49.4 | 49.0 | 48.4 | 49.2 | 48.4 | 49.5 | 48.4 | 48.4 | 48.4 | 48.4 |
| concentration | | | | | | | | | | | |
| (mass %) | | | | | | | | | | | |

| | | Example | | | Comparative Example | | | | | |
|---|---|---|---|---|---|---|---|---|---|---|
| Component | Type | 12 | 13 | 14 | 1 | 2 | 3 | 4 | 5 | 6 |
| Polymer | A-1 | 44 | | | | 45 | | | 17 | |
| | A-2 | | | 44 | | | | | | |
| | A-3 | | | | | | | | | |
| | A-4 | | 26 | | 23 | | | | | |
| | A-5 | | | | | | | | | |
| | a-1 | | | | | | 40 | | | |
| | a-2 | | 20 | | 23 | | | | | 22 |
| | a-3 | | | | | | | 45 | | |
| | a-4 | | | | | | | | | 23 |
| Photoacid | B-1 | | | | 3 | | | 3 | | |
| generator | B-2 | | | 0.5 | | | | | 3 | 3 |
| | B-3 | | | | | 4 | | | | |
| | B-4 | 4 | | | | | | | | |
| | B-5 | | 2.5 | 4 | | | | | | |
| | b-1 | | | | | | 10 | | | |
| Quencher | D-1 | 0.12 | | | 0.12 | | | | 0.12 | 0.12 |
| | D-2 | | 0.02 | 0.02 | | 0.04 | | 0.12 | | |
| Surfactant | F-1 | 0.01 | 0.01 | 0.01 | 0.01 | 0.01 | 0.01 | 0.01 | 0.01 | 0.01 |
| Additive | G-1 | | 0.3 | 0.3 | 0.3 | | | | | |
| | G-2 | | | | | 0.3 | | | | |
| | G-3 | 0.3 | | | | | | | 0.3 | 0.3 |
| 3-Ethoxyethyl | | 80 | 60 | 80 | 0 | 0 | 20 | 40 | 20 | 60 |
| propionate | | | | | | | | | | |
| Another | C-1 | 20 | | | 100 | | | | | |
| solvent | C-2 | | 40 | | | | | | | |
| | C-3 | | | | | | | 60 | | |
| | C-4 | | | | | 100 | 80 | | | |
| | C-5 | | | 20 | | | | | 80 | 40 |

| | | | | | | | | | |
|---|---|---|---|---|---|---|---|---|---|
| Solid content | 48.4 | 48.8 | 48.8 | 49.4 | 49.4 | 50.0 | 48.1 | 20.4 | 48.4 |
| concentration | | | | | | | | | |
| (mass %) | | | | | | | | | |

TABLE 3

| | Thick film coating | Application | Pattern | Plating |
|---|---|---|---|---|
| | applicability | bubbles | shape | shape |
| Example 1 | ◯ | ◯◯ | ◯ | ◯ |
| Example 2 | ◯ | ◯◯ | ◯ | ◯ |
| Example 3 | ◯ | ◯◯ | ◯ | ◯ |
| Example 4 | ◯ | ◯ | ◯ | ◯ |
| Example 5 | ◯ | ◯◯ | ◯ | ◯ |
| Example 6 | ◯ | ◯◯ | ◯ | ◯ |
| Example 7 | ◯ | ◯ | ◯ | ◯ |
| Example 8 | ◯ | ◯ | ◯ | ◯ |
| Example 9 | ◯ | ◯ | ◯ | ◯ |
| Example 10 | ◯ | ◯ | ◯ | ◯ |
| Example 11 | ◯ | ◯ | ◯ | ◯ |
| Example 12 | ◯ | ◯ | ◯ | ◯ |
| Example 13 | ◯ | ◯ | ◯ | ◯ |
| Example 14 | ◯ | ◯ | ◯ | ◯ |
| Comparative | ◯ | X | ◯ | X |
| Example 1 | | | | |
| Comparative | ◯ | Δ | ◯ | X |
| Example 2 | | | | |
| Comparative | ◯ | X | X | X |
| Example 3 | | | | |
| Comparative | ◯ | ◯ | Δ | Δ |
| Example 4 | | | | |
| Comparative | X | ◯ | — | — |
| Example 5 | | | | |
| Comparative | ◯ | ◯ | ◯ | Δ |
| Example 6 | | | | |

1: A photosensitive resin composition comprising:
a polymer (A) that comprises: a structural unit having a phenolic hydroxy group; and a (meth)acrylate-derived structural unit having an acid-dissociable group;
a photoacid generator (B); and
an organic solvent (C) that comprises 3-ethoxyethyl propionate,
wherein a solid content concentration of the photosensitive resin composition is 30 mass % or more.

2: The photosensitive resin composition according to claim 1, wherein the photoacid generator (B) comprises a compound represented by formula (B1): 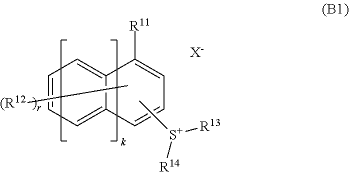
wherein, in the formula (B1), R¹¹ is a hydrogen atom, a fluorine atom, a hydroxy group, an alkyl group having 1 to 10 carbon atoms, an alkoxy group having 1 to 10 carbon atoms, or an alkoxycarbonyl group having 2 to 11 carbon atoms, R¹² is an alkyl group having 1 to 10 carbon atoms, an alkoxy group having 1 to 10 carbon atoms, an alkanesulfonyl group or an arylthio group having 1 to 10 carbon atoms, R¹³ and R¹⁴ are each independently an unsubstituted or substituted alkyl group having 1 to 10 carbon atoms, an unsubstituted or substituted phenyl group or naphthyl group, or R¹³ and R¹⁴ are bonded to each other to form a divalent group having 2 to 10 carbon atoms, k is an integer of 0 to 2, r is an integer of 0 to 10, X⁻ is PF₆⁻, BF₄⁻, (CF₃CF₂)₃PF₃⁻, (C₆F₅)₄B⁻, ((CF₃)₂C₆H₃)₄B⁻, or an anion represented by any of formulae (b-1) to (b-4):
R¹⁵CₚH_{q}FᵣSO₃⁻: (b-1)
R¹⁵SO₃⁻: (b-2)
wherein, in formulae (b-1) and (b-2), R¹⁵ is a hydrogen atom, a fluorine atom, or a substituted or unsubstituted hydrocarbon group having 1 to 12 carbon atoms, p is an integer of 1 to 10, q and r are integers satisfying 2p=q+r, and r≠0, 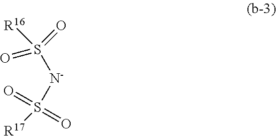
wherein, in formula (b-3), R¹⁶ and R¹⁷ are each independently a fluorine-substituted alkyl group having 1 to 10 carbon atoms, or R¹⁶ and R¹⁷ are bonded to each other to form a divalent fluorine-substituted alkylene group having 2 to 10 carbon atoms, and 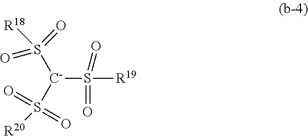
wherein, in formula (b-4), R¹⁸, R¹⁹, and R²⁰ are each independently a fluorine-substituted alkyl group having 1 to 10 carbon atoms, and optionally two of R¹⁸, R¹⁹, and R²⁰ are bonded to each other to form a divalent fluorine-substituted alkylene group having 2 to 10 carbon atoms.

3: The photosensitive resin composition according to claim 1, wherein the organic solvent (C) further comprises an organic solvent which is other than 3-ethoxyethyl propionate and has a boiling point in a range of 120° C. to 180° C.

4: The photosensitive resin composition according to claim 1, wherein the organic solvent (C) comprises at least one organic solvent selected from the group consisting of propylene glycol methyl ether acetate (PGMEA), 3-methoxybutyl acetate (3MBA), 3-methoxymethyl propionate, diethylene glycol methyl ethyl ether, 2-heptanone, and ethyl lactate.

5: The photosensitive resin composition according to claim 1, wherein the organic solvent (C) comprises at least one organic solvent selected from the group consisting of propylene glycol methyl ether acetate and 3-methoxybutyl acetate.

6: The photosensitive resin composition according to claim 1, wherein the organic solvent (C) comprises 20 mass % or more of 3-ethoxyethyl propionate.

7: A method for producing a resist pattern film, the method comprising:
applying the photosensitive resin composition according to claim 1 onto a substrate to form a resin coating film;
exposing the resin coating film to light; and
developing the resin coating film after exposure to form a resist pattern.

8: The method according to claim 7, wherein the resist pattern is a line-and-space pattern.

9: The method according to claim 7, wherein the resist pattern is a circular or polygonal columnar pattern.

10: The method according to claim 7, wherein a film thickness of the resin coating film is 20 μm or more.

11: A method for producing a plated shaped article, the method comprising:
producing a resist pattern film by the method according to claim 7; and
performing a plating treatment on the substrate using the resist pattern film as a mask to obtain the plated shaped article.

12: The method according to claim 11, wherein the plated shaped article has a line shape.

13: The method according to claim 11, wherein the plated shaped article has a circular or polygonal columnar pattern.
